(19) United States
(12) Patent Application Publication
(10) Pub. No.: US 2025/0062738 A1
(43) Pub. Date: Feb. 20, 2025

(54) MULTIMETER-WAVE ACOUSTIC RESONATORS

(71) Applicant: BOARD OF REGENTS, THE UNIVERSITY OF TEXAS SYSTEM, Austin, TX (US)

(72) Inventors: Ruochen Lu, Austin, TX (US); Jack Kramer, Austin, TX (US); Sinwoo Cho, Austin, TX (US); Omar Barrera, Austin, TX (US); Vakhtang Chulukhadze, Austin, TX (US)

(21) Appl. No.: 18/807,407

(22) Filed: Aug. 16, 2024

Related U.S. Application Data
(60) Provisional application No. 63/519,911, filed on Aug. 16, 2023.

(51) Int. Cl. H03H 9/02; H03H 3/08; H03H 9/25; H03H 9/64

(52) U.S. Cl. CPC H03H 9/02015; H03H 3/08; H03H 9/02551; H03H 9/25; H03H 9/6483

(57) ABSTRACT

Exemplary multimeter-wave acoustic resonators and methods employing intermediate layers in the fabricating of piezoelectric devices based on thin-film lithium niobate/lithium tantalate or aluminum nitride/scandium aluminum nitride on a substrate in a film stack that can use higher order first and third antisymmetric bulk acoustic tones. In some embodiments, the acoustic resonator comprises a base substrate of a material with low electromagnetic loss, a piezoelectric film layer that is suspended over the base substrate, and an interdigitated electrode (IDE) array formed by a pair of independently addressable microelectrode arrays disposed on a top surface of the piezoelectric film layer to resonantly vibrate at a range of frequencies greater than 6 GHz. The piezoelectric film layer was formed over an intermediate or sacrificial layer positioned between the base substrate and the piezoelectric film layer and then etched to provide the piezoelectric film layer suspended over the base substrate.

### RELATED APPLICATION

This PCT application claims priority to, and the benefit of, U.S. Provisional Patent Application No. 63/519,911, filed Aug. 16, 2023, entitled, “MULTIMETER-WAVE ACOUSTIC RESONATORS,” which is incorporated by reference herein in its entirety.

### STATEMENT REGARDING FEDERALLY SPONSORED RESEARCH OR DEVELOPMENT

This invention was made with government support under grant no. HR0011-22-2-0031 awarded by the Defense Advanced Research Projects (DARPA). The government has certain rights in the invention.

### BACKGROUND

Radio frequency (RF) acoustic devices are the dominant sub-6 GHz filter solution in mobile equipment and devices. Acoustic resonators, where electromagnetic (EM) energy is converted into and stored as mechanical vibration, feature two advantages compared to EM counterparts; namely, they are generally smaller in size (e.g., four to five orders of magnitude shorter wavelength, λ) and experience lower losses. So far, piezoelectric devices based on thin-film lithium niobate/lithium tantalate (LiNbO₃/LiTaO₃) and aluminum nitride/scandium aluminum nitride (AlN/ScAlN) have shown the best performance at sub-6 GHz, thanks to their high electromechanical coupling (k²), quality factor (Q), and consequently high figure of merit (FoM, Q·k²). If acoustic devices may be frequency scaled into millimeter-wave (mmWave) while maintaining high FoM, more compact 5G/6G signal processing elements may be feasible.

However, implementing high FoM acoustic resonators at mmWave has been a long-standing challenge. The issue originates from the short λ at higher frequencies, e.g., sub-100 nm λ at 60 GHz, which inevitably leads to sub-50 nm lateral feature size or piezoelectric film thickness. Such devices experience reduced Q due to resistive loss and surface damping. Alternatively, one can operate with higher-order Lamb modes for frequency scaling without relying on thin films, but k² decays dramatically with increased mode orders due to internal charge cancellation. Thus far, the FoM of 60 GHz resonators has fallen below 0.1, due to minimal k² and Q.

### SUMMARY

Exemplary multimeter-wave acoustic resonators and methods are disclosed employing intermediate layers in the fabricating of piezoelectric devices based on thin-film lithium niobate/lithium tantalate or aluminum nitride/scandium aluminum nitride on a substrate in a film stack that can use higher order first and third antisymmetric bulk acoustic tones. The exemplary multimeter-wave acoustic resonators can operate with high electromechanical coupling (k²), quality factor (Q), and high figure of merit (FoM, Q·k₂) and can operate at frequency-scaled into millimeter-wave (mmWave) while maintaining high FoM, that can provide more compact 5G/6G signal processing components and devices.

A study was conducted that designed and fabricated an acoustic resonator at 57 GHz with a high electromechanical coupling (k2) of 7.3% and 3-dB quality factor (Q) of 56, collectively enabling a record-breaking figure of merit (FoM, Q·k2) of 4.1, an order of magnitude higher than the state-of-the-art acoustic resonators. The device leverages the third-order antisymmetric (A3) Lamb mode in 110 nm 128° Y-cut lithium niobate (LiNbO3) piezoelectric thin film. A new film stack, namely transferred thin-film LiNbO3 on sapphire substrate with an intermediate amorphous silicon (Si) layer, facilitates the record-breaking performance at millimeter-wave (mmWave). The acoustic resonator features a compact footprint of 0.006 mm².

In another device, the study developed a piezoelectric acoustic filter in periodically poled piezoelectric film (P3F) lithium niobate (LiNbO3) at 23.8 GHz with low insertion loss (IL) of 1.52- and 3-dB fractional bandwidth (FBW) of 19.4%. The filter features a compact footprint of 0.64 mm2. The third-order ladder filter is implemented with electrically coupled resonators in 150 nm bi-layer P3F 128° rotated Y-cut LiNbO3 thin film, operating in second-order symmetric (S2) Lamb mode.

The study also developed and evaluated a 50.74 GHz lithium niobate (LiNbO3) acoustic resonator with a high-quality factor (Q) of 237 and an electromechanical coupling (k2) of 5.17%, resulting in a figure of merit (FoM, Q·k2) of 12.2. The LiNbO3 resonator employs a bilayer periodically poled piezoelectric film (P3F) 128° Ycut LiNbO3 on amorphous silicon (a-Si) on sapphire stack to achieve low losses and high coupling at millimeter wave (mmwave).

The study also developed an acoustic filter at 23.5 GHz with a low insertion loss (IL) of 2.38 dB and a 3-dB fractional bandwidth (FBW) of 18.2%, significantly surpassing the state-of-the-art. The device leverages electrically coupled acoustic resonators in 100 nm 128° Y-cut lithium niobate (LiNbO3) piezoelectric thin film, operating in the first-order antisymmetric (A1) mode. A new film stack, namely transferred thin-film LiNbO3 on silicon (Si) substrate with an intermediate amorphous silicon (a-Si) layer, facilitates the record-breaking performance at millimeter-wave (mmWave).

The study also developed a three-layer periodically poled piezoelectric film (P3F) lithium niobate resonator. The exemplary platform allows for high series 3 dB quality factor (Q) resonances, including Q up to 811 at 12.98 GHz. The trilayer film stack employs the use of three lithium niobate layers with alternating orientations on an intermediate amorphous bonding layer and sapphire substrate. The trilayer platform enables the use of high order Lamb modes with high Q thanks to the comparatively large thickness of the film when compared to monolayer counterparts.

Additional examples of filters and resonators are provided herein.

In an aspect, an acoustic resonator is disclosed comprising a base substrate of a material with low electromagnetic (EM) loss at frequencies greater than 6 GHz (e.g., sapphire, diamond); a piezoelectric film layer of lithium niobate (LiNbO₃), lithium tantalate (LiTaO₃), or scandium aluminum nitride, wherein the piezoelectric film layer is suspended over the base substrate; and an interdigitated electrode (IDE) array formed by a pair of independently addressable microelectrode arrays disposed on a top surface of the piezoelectric film layer, the interdigitated electrode (IDE) array being configured to resonantly vibrate at a range of frequencies greater than 6 GHz, wherein the piezoelectric film layer was formed over an intermediate or sacrificial layer (e.g., amorphous silicon, poly silicon, single crystal Si, zinc oxide, benzocyclobutene) positioned between the base substrate and the piezoelectric film layer and then etched, or partially etched, such that the piezoelectric film layer is suspended over the base substrate.

In some embodiments, the intermediate layer comprises at least one of amorphous silicon (a-Si), zinc oxide, polycrystalline silicon, single crystal silicon, or benzocyclobutene.

In some embodiments, the intermediate or intermediate layer comprises 1 μm thick layer of amorphous silicon, wherein the intermediate layer serves a sacrificial layer.

In some embodiments, the base substrate comprising the material with low EM loss at frequencies greater than 6 GHz is sapphire.

In some embodiments, the base substrate comprising the material with low EM loss at frequencies greater than 6 GHz is at least one of diamond, quartz, silicon carbide.

In some embodiments, the base substrate is 500 μm thick.

In some embodiments, the piezoelectric film layer comprises rotated Y-cut LiNbO₃.

In some embodiments, the pair of independently addressable microelectrode arrays are formed of aluminum.

In some embodiments, each electrode of the IDE array is between 1 μm and 100 μm, wherein each electrode of the IDE array is separated by 1 μm and 100 μm.

In some embodiments, the piezoelectric film layer is formed as a single layer of lithium niobate (LiNbO₃), a single layer of lithium tantalate (LiTaO₃), or a single layer of scandium aluminum nitride.

In some embodiments, the piezoelectric film layer comprises two or more distinct layers of lithium niobate (LiNbO₃), two or more distinct layers of lithium tantalate (LiTaO₃), or two or more distinct layers of scandium aluminum nitride (ScAlN).

In some embodiments, the piezoelectric film layer comprises three or more distinct layers of lithium niobate (LiNbO₃), three or more distinct layers of lithium tantalate (LiTaO₃), or three or more distinct layers of scandium aluminum nitride.

In some embodiments, the piezoelectric film layer comprises two or more distinct layers of lithium niobate (LiNbO₃), lithium tantalate (LiTaO₃), or a combination thereof.

In some embodiments, the resonator is employed in a thin-film bulk acoustic wave resonator (FBAR), a surface acoustic wave (SAW) device, or a mmWave acoustic filter, actuators for digital light processors, or actuators for the opto-quantum device.

In some embodiments, a non-release portion of the intermediate or sacrificial layer is employed as a capacitor or inductor (e.g., for filter performance enhancement).

In an aspect, an integrated circuit is disclosed comprising a radio-frequency (RF) formed of acoustic resonators of any one of the disclosed methods.

In some embodiments, a first acoustic resonator is employed as a series resonator, and a second acoustic resonator is employed as a shunt resonator in the RF filter, wherein the first and second acoustic resonators are each configured with the acoustic resonator of any one of the disclosed methods.

In some embodiments, the integrated circuit described herein comprises a series resonator and two identical shunt resonators each configured with the acoustic resonator of any one of the disclosed methods.

In an aspect, a method of fabricating an acoustic resonator is disclosed comprising bonding an intermediate layer (e.g., amorphous silicon (a-Si), poly-Si, single crystal Si, Zinc oxide) to a base substrate of a material with low electromagnetic (EM) loss at frequencies greater than 6 GHz; bonding a piezoelectric film layer of lithium niobate (LiNbO₃), lithium tantalate (LiTaO₃), or scandium aluminum nitride to the intermediate layer; etching a cavity at least into the piezoelectric film layer to define an interdigitated electrode (IDE) array on a top surface of the piezoelectric film layer, the IDE array formed by a pair of independently addressable microelectrode arrays; and etching a portion of the sacrificial layer disposed between the piezoelectric film layer and the base substrate to release the piezoelectric film layer from the base substrate such that at least a portion of the piezoelectric film layer is suspended over the base substrate.

### BRIEF DESCRIPTION OF THE DRAWINGS

The accompanying drawings, which are incorporated in and constitute a part of this specification, illustrate embodiments and, together with the description, serve to explain the principles of the methods and systems.

Embodiments of the present invention may be better understood from the following detailed description when read in conjunction with the accompanying drawings. Such embodiments, which are for illustrative purposes only, depict novel and non-obvious aspects of the invention. The drawings include the following figures.

FIGS. 1A-1C show an example acoustic resonator comprising a base substrate, a piezoelectric film layer, an interdigitated electrode array comprising two independently addressable microelectrode arrays, and a sacrificial layer.

FIG. 2A shows an example acoustic resonator having a piezoelectric film layer formed by a single layer of lithium niobate (LiNbO₃).

FIG. 2B shows an example acoustic resonator having a piezoelectric film layer formed by two distinct layers of lithium niobate (LiNbO₃).

FIG. 2C shows an example acoustic resonator having a piezoelectric film layer formed by three distinct layers of lithium niobate (LiNbO₃).

FIG. 2D shows an example acoustic resonator having a piezoelectric film layer formed by a single layer of lithium niobate (LiNbO₃) and a base substrate of either aluminum oxide (Al₂O₃) or silicon (Si).

FIG. 3 shows an example operational flow of the fabrication method of an exemplary acoustic resonator.

FIG. 4 shows an example mmWave acoustic resonator comprising a combination of one series portion of resonators and two identical shunt portions of resonators.

FIGS. 5A-5C shows, for a first example prototype, experimental results for a 1-layer acoustic resonator and features thereof. Specifically, FIG. 5A shows the first-order antisymmetric (A1) and third-order antisymmetric (A3) modes of a state-of-the-art (SoA) acoustic resonator and a 1-layer acoustic resonator using eigenmode finite element analysis (FEA) dispersion simulation. FIG. 5B shows simulated admittance, phase, and thickness-shear stress (T_{xz}) of the 1-layer acoustic resonator. FIG. 5C shows an example Butterworth-Van Dyke (BVD) model with two motional branches and a series inductor (Lₛ) for capturing EM effects.

FIG. 6 shows, for a second example prototype, experimental results for a 2-layer acoustic resonator and features thereof. Specifically, FIG. 6 shows the admittance, first-order antisymmetric (A1) mode, and third-order antisymmetric (A3) mode (i.e., stress) profiles of the 2-layer acoustic resonator using COMSOL (i.e., an analyzer, solver, and simulation software package for physics and engineering applications) FEA simulation.

FIG. 7 shows, for a third example prototype, experimental results for a 3-layer acoustic resonator. Specifically, FIG. 7 shows an example admittance and mode (i.e., stress) profiles of the 3-layer acoustic resonator using COMSOL FEA simulation.

FIGS. 8A-8C show, for a fourth example prototype, experimental results for a 1-layer-resonator-based filter. Specifically, FIG. 8A shows simulated A1 resonator admittance and filter response of the first 1-layer-resonator-based filter. FIG. 8B shows an example modified Butterworth-Van Dyke (MBVD) model configured to extract geometric parameters of an acoustic resonator. FIG. 8C shows simulated A1 resonator admittance and filter response of a second 1-layer-resonator-based filter.

FIG. 9A shows, for a fifth example prototype, the admittance, phase, and filter response of a 2-layer-resonator-based filter using COMSOL FEA simulation.

FIG. 9B shows, for a sixth example prototype, the admittance and filter response of an Al₂O₃/Si-based filter using COMSOL FEA simulation.

FIGS. 10A-10H shows, for the first example prototype, additional experimental results for a 1-layer acoustic resonator and features thereof. FIG. 10A shows the scanning electron microscopy (SEM) image of the LiNbO₃—Si-sapphire stack. FIG. 10B shows the symmetric ω:2θ of the (0114) reflection on the LiNbO₃ film. FIG. 10C shows the symmetric (0114) X-ray diffraction (XRD) rocking curve of the LiNbO₃ layer. FIG. 10D shows the fabrication process of the 1-layer acoustic resonator. FIG. 10E shows the measurement values of the amplitude and phase of the admittance of a fabricated 1-layer acoustic resonator. FIG. 10F shows zoomed-in admittance and Bode Quality factor (Q) of A1 and A3 modes of the fabricated 1-layer acoustic resonator. FIG. 10G shows the measured admittance and phase of a LiNbO₃—Si-Sapphire stack with a conventional LiNbO₃—Si stack. FIG. 10H shows extracted Figure of Merit (FoM), e.g., electromechanical coupling (k²) and quality factor (Q), of the fabricated 1-layer acoustic resonator and the state-of-the-art (SoA) resonator.

FIGS. 11A-11C, for the second example prototype, additional experimental results for a 2-layer acoustic resonator and features thereof. Specifically, FIG. 11A shows the transmission electron microscope (TEM) cross-sectional image of a film stack selected for a fabricated 2-layer acoustic resonator and the optical image of the fabricated 2-layer acoustic resonator. FIG. 11B shows the measured admittance and phase curves of the fabricated 2-layer acoustic resonator. FIG. 11C shows the Figure of Merit (FoM, Qk²) of the fabricated 2-layer acoustic resonator and the SoA resonator.

FIGS. 12A-12C, for the third example prototype, additional experimental results for the 3-layer acoustic resonator and features thereof. Specifically, FIG. 12A shows the bright-field scanning transmission scanning electron microscopy (BF STEM) image of the cross-section of a film stack selected for a fabricated 3-layer acoustic resonator and an optical image of the fabricated 3-layer acoustic resonator. FIG. 12B shows the raw and fitted measured response of the fabricated 3-layer acoustic resonator. FIG. 12C shows the quality factor Q and a (frequency×quality factor) product (fQ) of the fabricated 3-layer acoustic resonator and the SoA acoustic resonators (e.g., AIN, AIScN, prior LiNbO₃).

FIGS. 13A-13H shows, for the fourth example prototype, additional experimental results for the 1-layer-resonator-based filter and features thereof. Specifically, FIG. 13A shows the cross-sectional TEM image of a film stack selected for the first fabricated 1-layer-resonator-based filter and an X-ray diffraction (XRD) symmetric reflection of the piezoelectric layer in the film stack. FIG. 13B shows the optical images of the first fabricated 1-layer-resonator-based filter comprising a series resonator and two shunt resonators, wherein each series and shunt resonator is a fabricated 1-layer acoustic resonator. FIG. 13C shows the admittance and phase of the fabricated series and shunt resonators in the first fabricated 1-layer-resonator-based filter fitted with the modified Butterworth-Van Dyke (MBVD) circuit model. FIG. 13D shows the measured filter response for the first fabricated 1-layer-resonator-based filter. FIG. 13E shows the insertion loss (IL) and fractional bandwidth (FWB) of the first fabricated 1-layer-resonator-based filter and the SoA acoustic filters. FIG. 13F shows the optical images of the fabricated 1-layer series resonator, the fabricated 1-layer shunt resonator, and a second fabricated 1-layer-resonator-based filter. FIG. 13G shows the measured and MBVD-fitted admittance response and phase response of the fabricated series and shunt resonators in the second fabricated 1-layer-resonator-based filter. FIG. 13H shows the measured raw filter data transmission and reflection under 50Ω and 39+j17Ω impedances for each fabricated shunt resonator in the second fabricated 1-layer-resonator-based filter.

FIGS. 14A-14D shows, for the fifth example prototype, additional experimental results for the 2-layer-resonator-based filter and features thereof. Specifically, FIG. 14A shows the optical images of a fabricated 2-layer shunt resonator, a fabricated 2-layer series resonator, and a fabricated 2-layer-resonator-based filter. FIG. 14B shows the admittance response in amplitude and phase of the 2-layer resonators in the fabricated 2-layer-resonator-based filter, fit with the MBVD circuit model. FIG. 14C shows the measured raw filter data transmission and reflection under 50Ω and 34.7Ω impedances for each fabricated shunt resonator in the fabricated 2-layer-resonator-based filter. FIG. 14D shows the insertion loss (IL) and fractional bandwidth (FWB) of the fabricated 2-layer-resonator-based filter and the SoA acoustic filters.

FIGS. 15A-15F shows, for the sixth example embodiment, additional experimental results for the Al₂O₃/Si-based filter and features thereof. Specifically, FIG. 15A shows the full width at half maximum (FWHM) for an LN-aSi-Al₂O₃ film stack and an LN-aSi-Si film stack. FIG. 15B the example TEM cross-sectional images of the LN-aSi-Al₂O₃ and LN-aSi-Si stacks. FIG. 15C shows the optical images of the fabricated Al₂O₃-based series resonator (i.e., LN-aSi-Al₂O₃-based series resonator), the fabricated Al₂O₃-based shunt resonator (i.e., LN-aSi-Al₂O₃-based shunt resonator), the fabricated LN-aSi-Al₂O₃-based filter (i.e., Al₂O₃-based filter), and the fabricated Ln-aSi—Si-based filter (i.e., Si-based filter). FIG. 15D shows the measured and fitted admittance response for the fabricated Al₂O₃-based series and shunt resonators in the fabricated Al₂O₃-based filter. FIG. 15E shows the filter responses for the fabricated Al₂O₃-based filter and the fabricated Si-based filter. FIG. 15F shows the fractional bandwidth (FBW) and insertion loss (IL) of the fabricated Al₂O₃-based filter, the fabricated Si-based filter, and the state-of-the-art filters.

### DETAILED DESCRIPTION

Some references, which may include various patents, patent applications, and publications, are cited in a reference list and discussed in the disclosure provided herein. The citation and/or discussion of such references is provided merely to clarify the description of the disclosed technology and is not an admission that any such reference is “prior art” to any aspects of the disclosed technology described herein. In terms of notation, “[n]” corresponds to the nth reference in the list. For example, [1] refers to the first reference in the list, [1′] refers to the first reference in another list, and [1″] refers to the first reference in yet another list. All references cited and discussed in this specification are incorporated herein by reference in their entirety and to the same extent as if each reference was individually incorporated by reference.

### Example System #1

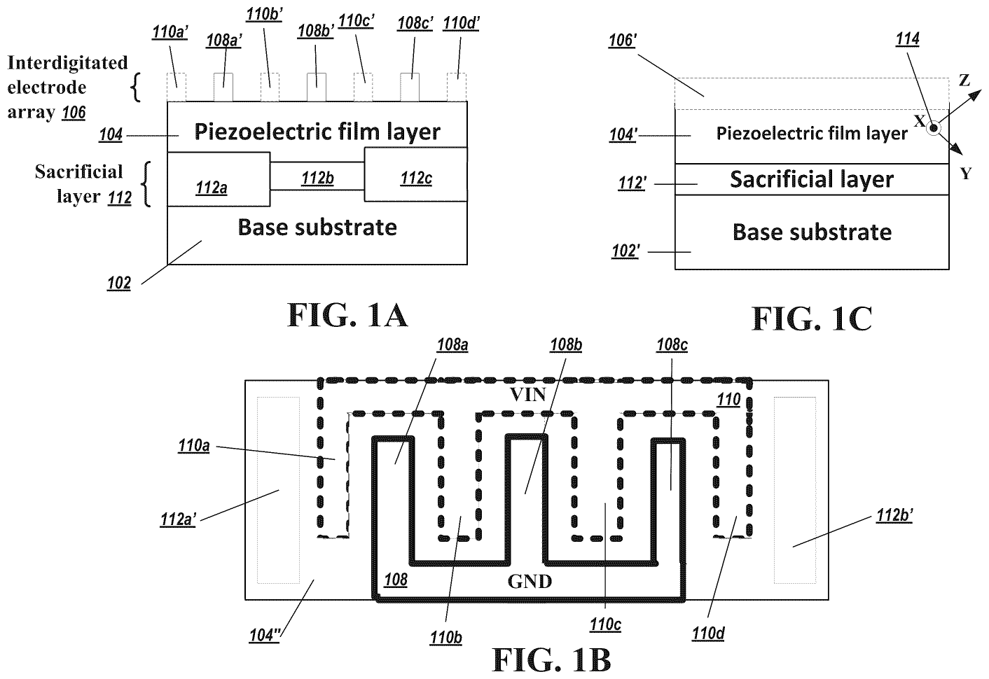

FIGS. 1A-1C show an example acoustic resonator comprising a base substrate 102 (also referred to as 102′), a piezoelectric film layer 104 (also referred to as 104′ and 104″), an interdigitated electrode array 106 (also referred to as 106′), and a sacrificial layer 112 (also referred to as 112′). Specifically, FIG. 1A shows a front view of the example acoustic resonator. As shown in FIG. 1A, the base substrate 102 is made of a material with low electromagnetic (EM) loss at frequencies greater than 6 GHz (e.g., sapphire, diamond, quartz, silicon carbide). The base substrate 102 is 500 μm thick.

The piezoelectric film layer 104 is made of lithium niobate (LiNbO₃), lithium tantalate (LiTaO₃), or scandium aluminum nitride (AlScN). The piezoelectric film layer is suspended over the base substrate 102. The piezoelectric film layer 104 is formed over a sacrificial (i.e., intermediate) layer 112 positioned between the base substrate 102 and the piezoelectric film layer 104 and then etched, or partially etched, such that the piezoelectric film layer 104 is suspended over the base substrate 102. The piezoelectric film layer 104 is formed by a single layer of LiNbO₃, a single layer of LiTaO₃, a single layer of AlScN, a combination of two or more distinct layers of LiNbO₃, a combination of two or more distinct layers of LiTaO₃, a combination of two or more distinct layers of AlScN, a combination of three or more distinct layers of LiNbO₃, a combination of three or more distinct layers of LiTaO₃, a combination of three or more distinct layers of AlScN, or a combination of two or more distinct layers of LiNbO₃ and LiTaO₃.

FIG. 1B shows a top view of the acoustic resonator. As shown in FIG. 1B, the interdigitated electrode (IDE) array 106 is formed by a pair of independently addressable microelectrode arrays 108 and 110. The addressable microelectrode array 108 serves as the ground (i.e., GND) array, and the addressable microelectrode array 110 serves as the input voltage array (i.e., VIN) of the acoustic resonator. In the example shown in FIG. 1B, the addressable microelectrode array 108 includes electrodes 108a (also referred to as 108a′), 108b (also referred to as 108b′), and 108c (also referred to as 108c′). The addressable microelectrode array 110 includes electrodes 110a (also referred to as 110a′), 110b (also referred to as 110b′), 110c (also referred to as 110c′), and 110d (also referred to as 110d′). Each electrode 108a, 108b, 108c, 108d, 110a, 110b, 110c, 110d, and 110e is between 1 μm and 100 μm thick. Additionally, each electrode 108a, 108b, 108c, 108d, 110a, 110b, 110c, 110d, and 110e is separated by 1 μm and 100 μm.

The sacrificial (i.e., intermediate) layer 112 comprises at least one of amorphous silicon (a-Si), zinc oxide, polycrystalline silicon, single crystal silicon, or benzocyclobutene layers 112a and 112c. Each layer 112a and 112c is 1 μm thick and is also referred to as the non-release portion of the sacrificial layer. Each non-release portion 112a and 112c is employed as a capacitor or inductor (e.g., for filter performance enhancement). The sacrificial layer 112 also includes an air gap 112b.

FIG. 1C shows a side view of the acoustic resonator. As shown in FIG. 1C, the piezoelectric film layer 104′ comprises rotated Y-cut 114 of LiNbO₃, LiTaO₃, or AlScN.

### Example System #2

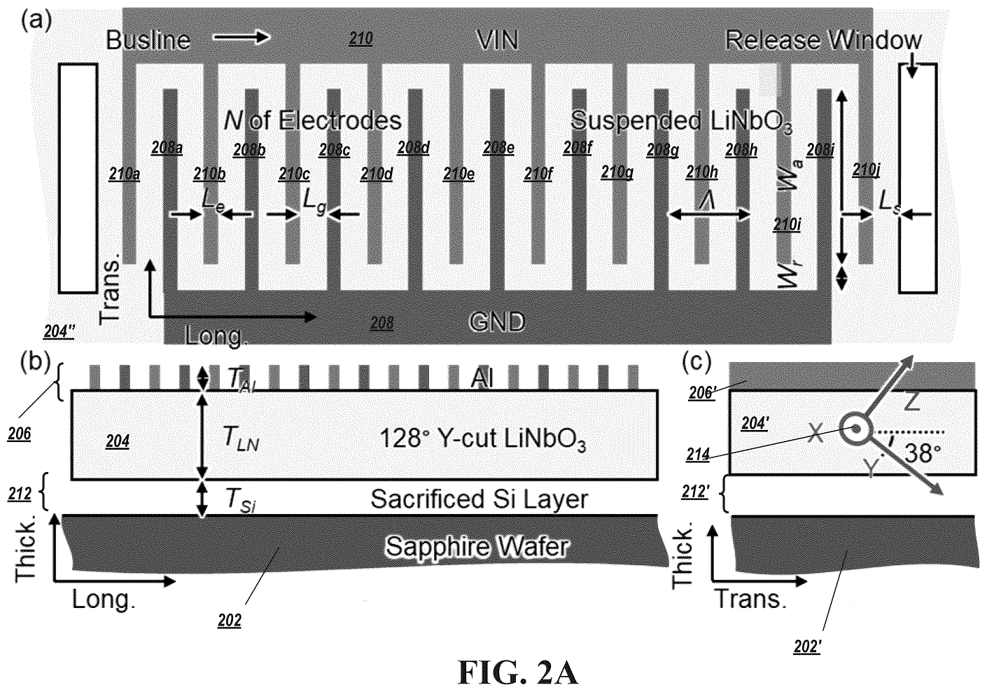

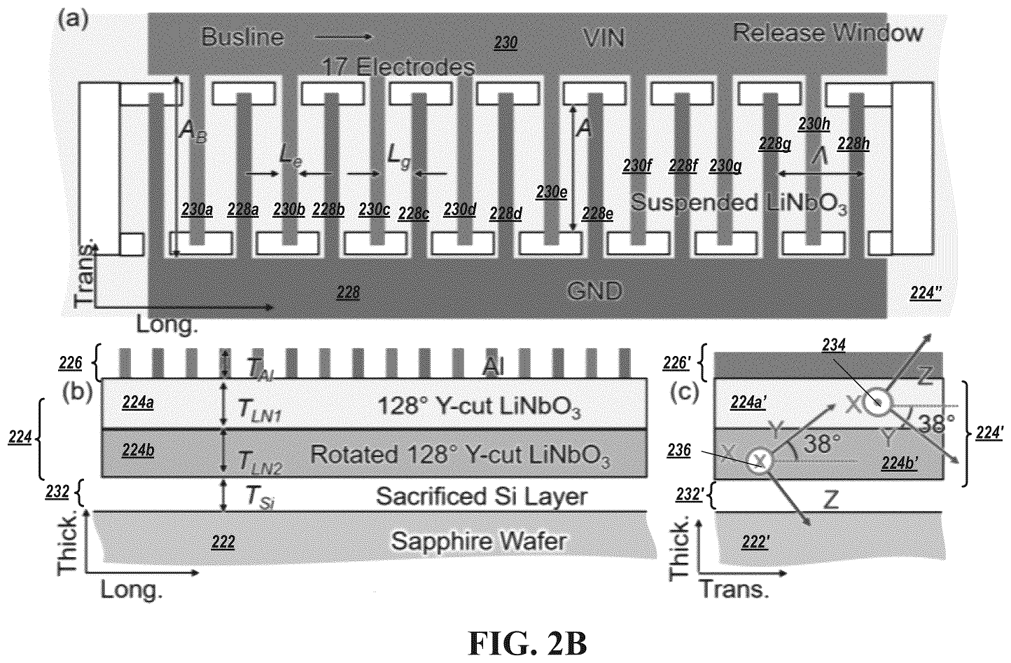

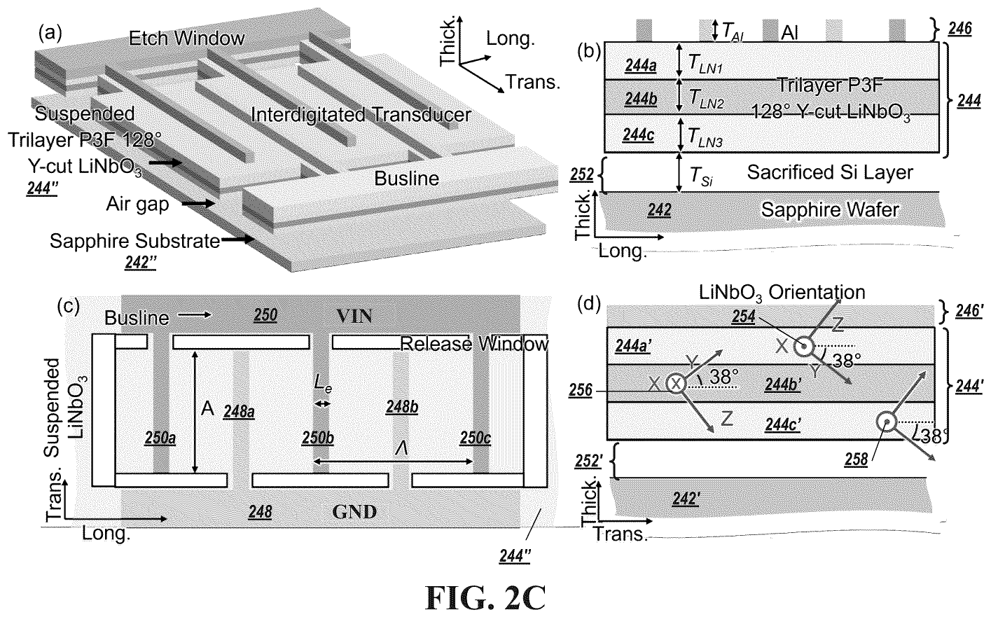

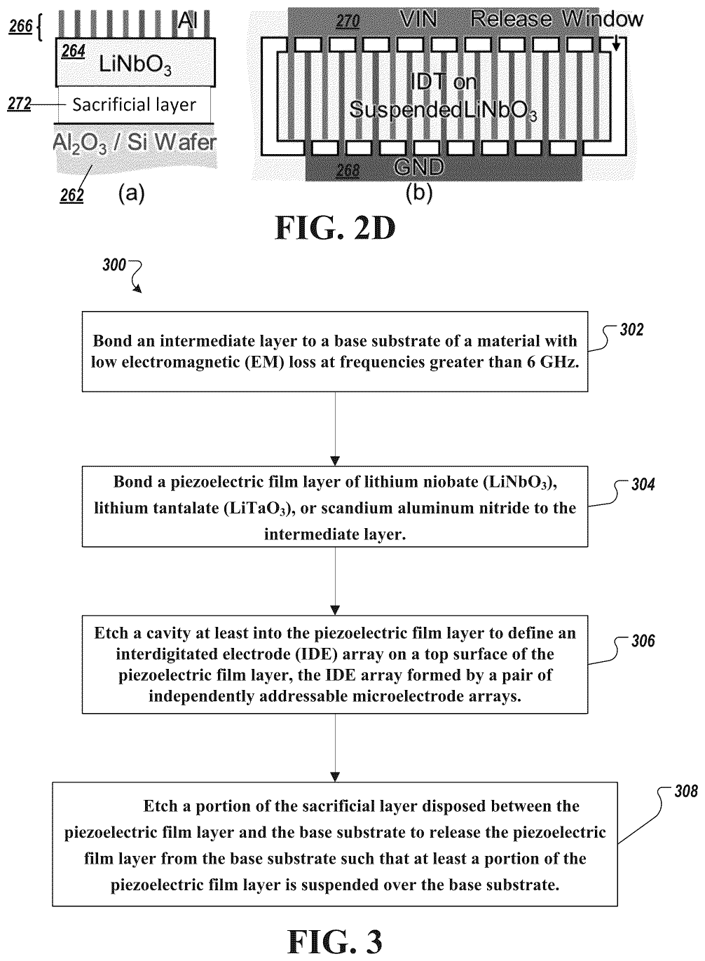

FIG. 2A shows an example acoustic resonator having a piezoelectric film layer formed by a single layer of lithium niobate (LiNbO₃), also referred to as a 1-layer acoustic resonator. In the example shown in FIG. 2A, the 1-layer acoustic resonator comprises a base substrate 202 (also referred to as 202′), a piezoelectric film layer 204 (also referred to as 204′ and 204″), an interdigitated electrode array 206 (also referred to as 206′), and a sacrificial layer 212 (also referred to as 212′).

Specifically, subpanel (b) shows a front view of the 1-layer acoustic resonator. As shown in subpanel (b), the base substrate 202 is made of sapphire and is also referred to as a sapphire wafer. The base substrate 202 is 500 μm-thick.

The piezoelectric film layer 204 is made of lithium niobate (LiNbO₃). The LiNbO₃ thickness (T_{LN}) of the film layer 204 is 110 nm. The piezoelectric film layer is suspended over the base substrate 202. The piezoelectric film layer 204 is formed over a sacrificial (i.e., intermediate) layer 212 positioned between the base substrate 202 and the piezoelectric film layer 204 and then etched, or partially etched, such that the piezoelectric film layer 204 is suspended over the base substrate 202.

High resistive amorphous Si (i.e., a-Si) is used for the sacrificial layer 212. The sacrificial layer thickness (T_{Si}) is 1 μm.

In FIG. 2A, Subpanel (a) shows a top view of the 1-layer acoustic resonator. As shown in subpanel (a), the interdigitated electrode (IDE) array 206 is formed by a pair of independently addressable microelectrode arrays 208 and 210. The addressable microelectrode array 208 serves as the ground (i.e., GND) array, and the addressable microelectrode array 210 serves as the input voltage array (i.e., VIN) of the 1-layer acoustic resonator.

The IDE array 206 is made of Aluminum (Al). The aluminum thickness (TAI) of the IDE array is 300 nm. The number of electrodes (N) in the pair of independently addressable microelectrode arrays 208 and 210 in total is 19.

The addressable microelectrode array 208 includes electrodes 208a-208i. The addressable microelectrode array 210 includes electrodes 210a-210i. Each electrode 208a-208i and 210a-210i has an electrode length (Lₑ) of 1.4 μm. The gap length (L_{g}) between each electrode is 2.6 μm, the aperture width (Wₐ) of each electrode is 37 μm, and the recessed width (Wᵣ) of each electrode is 2 μm. The cell length (i.e., pitch) (Λ) is 8 μm.

FIG. 2A, Subpanel (c) shows a side view of the 1-layer acoustic resonator. As shown in subpanel (c), the piezoelectric film layer 204′ comprises rotated Y-cut LiNbO₃ 214. The side length (Lₛ) of the 1-layer acoustic resonator is 2 μm.

Table 1 shows the geometric parameters for the 1-layer acoustic resonator.

TABLE 1

| Symbol | Parameter | Value | Symbol | Parameter | Value |
|---|---|---|---|---|---|
| Λ | Cell length (μm) | 8 | Wₐ | Aperture width (μm) | 37 |
| Lₑ | Electrode length (μm) | 1.4 | Wᵣ | Recessed width (μm) | 2 |
| L_{g} | Gap length (μm) | 2.6 | T_{LN} | LiNbO₃ thickness (nm) | 110 |
| Lₛ | Side length (μm) | 2 | T_{Al} | Aluminum thickness (nm) | 300 |
| N | Number of electrode | 19 | T_{Si} | Sacrificial Si thickness (μm) | 1 |

### Example System #3

FIG. 2B shows an example acoustic resonator having a piezoelectric film layer formed by two distinct layers of lithium niobate (LiNbO₃), also referred to as a 2-layer acoustic resonator. In the example shown in FIG. 2B, the 2-layer acoustic resonator comprises a base substrate 222 (also referred to as 222′), a piezoelectric film layer 224 (also referred to as 224′ and 224″) comprising two LiNbO₃ layers 224a (also referred to as 224a′) and 224b (also referred to as 224b′), an interdigitated electrode array 226 (also referred to as 226′), and a sacrificial layer 232 (also referred to as 232′). In the example shown in FIG. 2B, subpanel (b) shows a front view of the 2-layer acoustic resonator. As shown in subpanel (b), the base substrate 222 is made of sapphire and is also referred to as a sapphire wafer. The base substrate 222 is 500 μm-thick.

The piezoelectric film layer 224 includes two LiNbO₃ layers 224a and 224b. The LiNbO₃ thickness (T_{LN}) of the piezoelectric film layer 224 is 220 nm (i.e., each layer 224a and 224b is 110 nm). The piezoelectric film layer is suspended over the base substrate 222. The piezoelectric film layer 224 is formed over a sacrificial (i.e., intermediate) layer 232 positioned between the base substrate 222 and the piezoelectric film layer 224 and then etched, or partially etched, such that the piezoelectric film layer 224 is suspended over the base substrate 222. High resistive amorphous Si (i.e., a-Si) is used for the sacrificial layer 232. The sacrificial layer thickness (T_{Si}) is 1 μm.

FIG. 2B, Subpanel (a) shows a top view of the 2-layer acoustic resonator. As shown in subpanel (a), the interdigitated electrode (IDE) array 226 is formed by a pair of independently addressable microelectrode arrays 228 and 230. The addressable microelectrode array 228 serves as the ground (i.e., GND) array, and the addressable microelectrode array 230 serves as the input voltage array (i.e., V_{IN}) of the 2-layer acoustic resonator.

The IDE array 226 is made of Aluminum (Al). The aluminum thickness (T_{Al}) of the IDE array is 350 nm. The number of electrodes (N) the pair of independently addressable microelectrode arrays 228 and 230 have in total is 17. The addressable microelectrode array 228 includes electrodes 228a-228h. The addressable microelectrode array 230 includes electrodes 230a-230h. Each electrode 228a-228h and 230a-230h has an electrode length (Lₑ) of 800 nm. The gap length (L_{g}) between each electrode is 3.2 μm, and the aperture (A) of each electrode is 59 μm. The cell length (i.e., pitch) (Λ) is 8 μm. Etch windows 4 μm in height (not shown) are positioned in between the electrodes 228a-228h and 230a-230h with a 1 μm gap between the edge of the electrode and the etch window. Etch windows 5 μm wide define the edge of the resonator, and the distance (A_{B}) between the buslines (e.g., V_{IN}, GND) of the 2-layer acoustic resonator is 71 μm.

FIG. 2B, Subpanel (c) shows a side view of the 2-layer acoustic resonator. As shown in subpanel (c), the piezoelectric film layer 224′ comprises two bonded 128° Y-cut layers 224a′ and 224b′. The two layers are rotated 180° degrees relative to each other about the axis defined by the intersection of the YZ-plane and the 128° Y-cut plane. The layer 224a′ is rotated in the 234 direction, and the layer 224b′ is rotated in the 236 direction.

Table 2 shows the geometric parameters for the 2-layer acoustic resonator.

TABLE 2

| Symbol | Parameter | Value | Symbol | Parameter | Value |
|---|---|---|---|---|---|
| Λ | Cell length (μm) | 8 | A | Aperture (μm) | 59 |
| Lₑ | Electrode length (nm) | 800 | A_{B} | Buslines distance (μm) | 71 |
| L_{g} | Gap length (μm) | 3.2 | T_{LN} | LiNbO₃ thickness (nm) | 220 |
| N | Number of electrode | 17 | T_{Al} | Aluminum thickness (nm) | 350 |
| T_{Si} | Sacrificial Si thickness (μm) | 1 | | | |

### Example System #4

FIG. 2C shows an example acoustic resonator having a piezoelectric film layer formed by three distinct layers of lithium niobate (LiNbO₃), also referred to as a 3-layer acoustic resonator. In the example shown in FIG. 2C, the 3-layer acoustic resonator comprises a base substrate 242 (also referred to as 242′ and 242″), a piezoelectric film layer 244 (also referred to as 244′ and 244″), an interdigitated electrode array 246 (also referred to as 246′), and a sacrificial layer 252 (also referred to as 252′).

FIG. 2C, subpanel (b) shows a front view of the 3-layer acoustic resonator. As shown in subpanel (b), the base substrate 242 is made of sapphire and is also referred to as a sapphire wafer. The base substrate 242 is 500 μm-thick. The piezoelectric film layer 244 is made of lithium niobate (LiNbO₃). The piezoelectric film layer 244 is periodically poled, so it is also referred to as the periodically poled piezoelectric film (P3F) layer. The LiNbO₃ thickness (T_{LN}) of the film layer 244 is 370 nm (i.e., each layer 244a, 244b, and 244c is 123 nm). The piezoelectric film layer 244 is suspended over the base substrate 242.

The piezoelectric film layer 244 is formed over a sacrificial (i.e., intermediate) layer 252 positioned between the base substrate 242 and the piezoelectric film layer 244 and then etched, or partially etched, such that the piezoelectric film layer 244 is suspended over the base substrate 242.

High resistive amorphous Si (i.e., a-Si) is used for the sacrificial layer 252. The sacrificial layer thickness (T_{Si}) is 1 μm.

Subpanel (c) shows a top view of the 3-layer acoustic resonator. As shown in subpanel (c), the interdigitated electrode (IDE) array 246 is formed by a pair of independently addressable microelectrode arrays 248 and 250. The addressable microelectrode array 248 serves as the ground (i.e., GND) array, and the addressable microelectrode array 250 serves as the input voltage array (i.e., VIN) of the 3-layer acoustic resonator. The IDE array 246 is made of Aluminum (Al). The aluminum thickness (T_{Al}) of the IDE array is 350 nm. The number of electrodes (N) in the pair of independently addressable microelectrode arrays 248 and 250 in total is 5. The addressable microelectrode array 248 includes electrodes 248a-248b. The addressable microelectrode array 250 includes electrodes 250a-250c. Each electrode 248a-248b and 250a-250c has an electrode length (Lₑ) of 2.8 μm. The aperture (A) of each electrode is 34 μm, and the cell length (i.e., pitch) (Λ) is 28 μm.

Subpanel (d) shows a side view of the 3-layer acoustic resonator. As shown in subpanel (c), the piezoelectric film layer 244′ comprises three 128° Y-cut LiNbO₃ layers 244a′, 244b′, and 244c′. The orientation of the 128°Y-cut layers alternates between upward and downward orientations (e.g., 254, 256, 258), such that the material X axis of the upward-oriented film is aligned with the material-X axis of the downward-oriented film.

Table 3 shows the geometric parameters for the 3-layer acoustic resonator.

TABLE 3

| Symbol | Parameter | Value | Symbol | Parameter | Value |
|---|---|---|---|---|---|
| Λ | Cell length (μm) | 28 | A | Aperture (μm) | 34 |
| Lₑ | Electrode length (μm) | 2.8 | T_{LN} | LiNbO₃ thickness (nm) | 370 |
| N | Number of electrode | 5 | T_{Al} | Aluminum thickness (nm) | 350 |
| | | | T_{Si} | Sacrificial Si thickness (μm) | 1 |

### Example System #4

FIG. 2D shows an example acoustic resonator having a piezoelectric film layer formed by a single layer of lithium niobate (LiNbO₃) and a base substrate of either aluminum oxide (Al₂O₃) or silicon (Si). The example acoustic resonator shown in FIG. 2D is also referred to as an Al₂O₃/Si-based acoustic resonator. In the example shown in FIG. 2D, the Al₂O₃/Si-based acoustic resonator comprises a base substrate 262, a piezoelectric film layer 264 (also referred to as 264′), an interdigitated electrode array 266, and a sacrificial layer 272.

FIG. 2D, subpanel (a) shows a front view of the Al₂O₃/Si-based acoustic resonator. As shown in subpanel (a), the base substrate 262 is made of either Al₂O₃ or Si and is also referred to as either Al₂O₃ or Si wafer. The base substrate 262 is 500 μm-thick. The piezoelectric film layer 264 is made of lithium niobate (LiNbO₃). The LiNbO₃ thickness (T_{LN}) of the film layer 264 is 350 nm. The piezoelectric film layer 264 is suspended over the base substrate 262. The piezoelectric film layer 264 is formed over a sacrificial (i.e., intermediate) layer 272 positioned between the base substrate 262 and the piezoelectric film layer 264 and then etched, or partially etched, such that the piezoelectric film layer 264 is suspended over the base substrate 262. High resistive amorphous Si (i.e., a-Si) is used for the sacrificial layer 272.

Subpanel (b) shows a top view of the Al₂O₃/Si-based acoustic resonator. As shown in subpanel (b), the interdigitated electrode (IDE) array 266 is formed by a pair of independently addressable microelectrode arrays 268 and 270. The addressable microelectrode array 268 serves as the ground (i.e., GND) array, and the addressable microelectrode array 270 serves as the input voltage array (i.e., VIN) of the Al₂O₃/Si-based acoustic resonator. The IDE array 266 is made of Aluminum (Al). The aluminum thickness (TAI) of the IDE array is 350 nm. Each addressable microelectrode array 268 and 270 includes electrodes evenly spaced by 3 μm between each other.

### Example Fabrication Method

FIG. 3 shows the operational flow 300 of the fabrication method of an exemplary acoustic resonator, e.g., the device described in relation to FIGS. 1A-1C, 2, 3, and 4. At step 302, the fabrication method bonds an intermediate layer to a base substrate of a material with low electromagnetic (EM) loss at frequencies greater than 6 GHz. At step 304, the fabrication method bonds a piezoelectric film layer of lithium niobate (LiNbO₃), lithium tantalate (LiTaO₃), or scandium aluminum nitride (AlScN) to the intermediate layer. At step 306, the fabrication method etches a cavity at least into the piezoelectric film layer to define an interdigitated electrode (IDE) array on the top surface of the piezoelectric film layer; the IDE array is formed by a pair of independently addressable microelectrode arrays. At step 308, the fabrication method etches a portion of the sacrificial layer disposed between the piezoelectric film layer and the base substrate to release the piezoelectric film layer from the base substrate such that at least a portion of the piezoelectric film layer is suspended over the base substrate.

### Example mm Wave Acoustic Filter

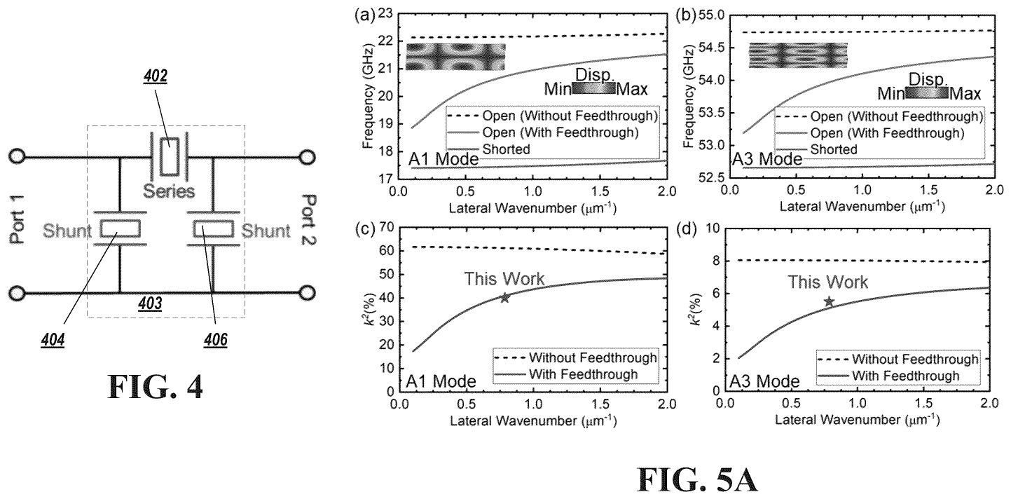

FIG. 4 shows an example mmWave acoustic resonator comprising a combination 403 of one series portion of resonators 402 and two identical shunt portions of resonators 404 and 406. The series portion 402 comprises one or more identical acoustic resonators connected in series. Each acoustic resonator (i.e., series resonator) in the series portion 402 is a 1-layer, 2-layer, 3-layer, or Al₂O₃/Si-based acoustic resonator. The shunt portion 404 comprises one or more identical acoustic resonators connected in series. Each acoustic resonator (i.e., shunt resonator) in the shunt portion 404 is a 1-layer, 2-layer, 3-layer, or Al₂O₃/Si-based acoustic resonator. The shunt portion 406 comprises one or more identical acoustic resonators connected in series. Each acoustic resonator (i.e., shunt resonator) in the shunt portion 406 is a 1-layer, 2-layer, 3-layer, or Al₂O₃/Si-based acoustic resonator.

The shunt portions 404 and 406 have the same number of shunt resonators, and every shunt resonator is identical to one another. The number of series resonators in the series portion 402 may be the same as or different from the number of shunt resonators in each shunt portion 404 and 406. Each series resonator in the series portion 402 is of the same or different type compared to each shunt resonator in each shunt portion 404 and 406. In FIG. 4, the combination 403 is further coupled with two ports of the filter (e.g., ports 1 and 2). One of the ports is an input port, and the other is an output port.

### Experimental Results and Additional Examples

A study was conducted to develop multimeter-wave acoustic resonators having high electromechanical coupling (k²), quality factor (Q), and, consequently, a high figure of merit (FoM, Q·k²). The exemplary acoustic resonators may be frequency-scaled into millimeter-wave (mmWave) while maintaining high FoM, providing more compact 5G/6G signal processing elements.

### Simulated Acoustic Resonators and Filters

Simulated 1-layer acoustic resonator. When the exemplary 1-layer acoustic resonator (details in FIG. 2A and Table 1) was in operation, the alternating electrical fields between electrodes excited higher-order antisymmetric modes, namely first-order antisymmetric (A1) and third-order antisymmetric (A3) modes, via piezoelectric coefficient e 15 [18].

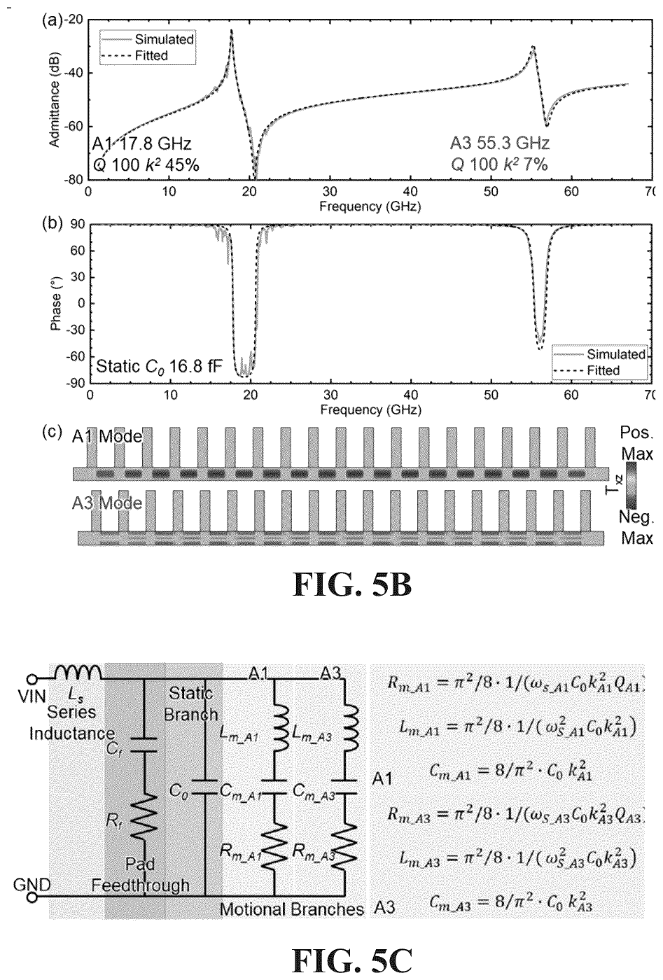

FIGS. 5A-5C shows, for a first example prototype, experimental results for a 1-layer acoustic resonator and features thereof. FIG. 5A shows the A1 and A3 modes of the state-of-the-art (SoA) acoustic resonator and the exemplary 1-layer acoustic resonator using eigenmode finite element analysis (FEA) dispersion simulation. Specifically, subpanels (a) and (b) show the A1 and A3 modes of the SoA acoustic resonator, and subpanels (c) and (d) show the A1 and A3 modes of the exemplary 1-layer acoustic resonator.

The study designed the lateral electrode dimensions of the exemplary 1-layer acoustic resonator based on the FEA dispersion simulations of the A1 and A3 modes of the SoA resonator shown in subpanels (a) and (b). The FEA setup followed a similar process reported in [18] but included additional capacitive feedthrough via air. Different from prior reported Lamb mode dispersion, where k² was larger for longer wavelength (λ), A1 and A3 modes of the exemplary 1-layer acoustic resonator showed reduced k² with longer λ in ultra-thin piezoelectric films due to more electrical field leakage via air as shown in subpanels (c) and (d).

The study then simulated the exemplary 1-layer acoustic resonator with frequency-domain FEA simulation. FIG. 5B shows the simulated admittance (subpanel a), phase (subpanel b), and thickness-shear stress (T_{xz}) (subpanel c) of the exemplary 1-layer acoustic resonator.

The study assigned mechanical Q of 100, as resonator loss at mmWave was not well studied [2]-[4]. The study obtained two resonances, i.e., A1 at 17.8 GHz (shown in subpanel a) and A3 at 55.3 GHz (shown in subpanel b), validating the prior eigenmode FEA. The thickness shear stress simulation shown in subpanel (c) highlighted the confined acoustic energy in the LiNbO₃ film layer of the exemplary 1-layer acoustic resonator.

FIG. 5C shows the Butterworth-Van Dyke model with two motional branches and a series inductor (Lₛ) for capturing EM effects [18]. After the simulation, the study extracted the parameters of the exemplary 1-layer acoustic resonator using the Butterworth-Van Dyke (BVD) model shown in FIG. 5C.

Table 4 shows fitted parameters of the exemplary 1-layer acoustic resonator from simulation and measurement.

TABLE 4

| Symbol | Simulated | | Measured | | Symbol | Simulated | | Measured | |
|---|---|---|---|---|---|---|---|---|---|
| C₀ | 16.8 | fF | 19.5 | fF | R_{f} | 0 | Ω | 100 | Ω |
| C_{f} | 0 | fF | 8.5 | fF | Lₛ | 0 | nH | 0.1 | nH |
| fₛ_{_{—}}_{A1} | 17.8 | GHz | 19.2 | GHz | fₛ_{_{—}}_{A3} | 55.3 | GHz | 57.0 | GHz |

| | | | | | |
|---|---|---|---|---|---|
| Perceived k_{A1}² | 45% | 29% | Extracted k_{A1}² | 45% | 40% |
| Perceived Q_{A1} | 100 | 54 | Extracted Q_{A1} | 100 | 55 |
| Perceived k_{A3}² | 7.0% | 7.3% | Extracted k_{A3}² | 7.0% | 5.5% |
| Perceived Q_{A3} | 100 | 56 | Extracted Q_{A3} | 100 | 60 |

As shown in Table 4, the simulation results of the exemplary 1-layer acoustic resonator showed a high k² of 45% for A1 and 7.0% for A3, and a static capacitance (C₀) of 16.8 fF. Pad feedthrough capacitance (C_{f}) and resistance (R_{f}), along with side length (Lₛ), from the simulation results were 0, as they were not included in frequency domain FEA simulation.

Simulated 2-layer acoustic resonator. The study simulated the exemplary 2-layer acoustic resonator (details in FIG. 2B and Table 2) using COMSOL (i.e., an analyzer, solver, and simulation software package for physics and engineering applications) finite element analysis (FEA) with an assumed LiNbO₃ thickness of 110 nm and Q of 200 for both layers.

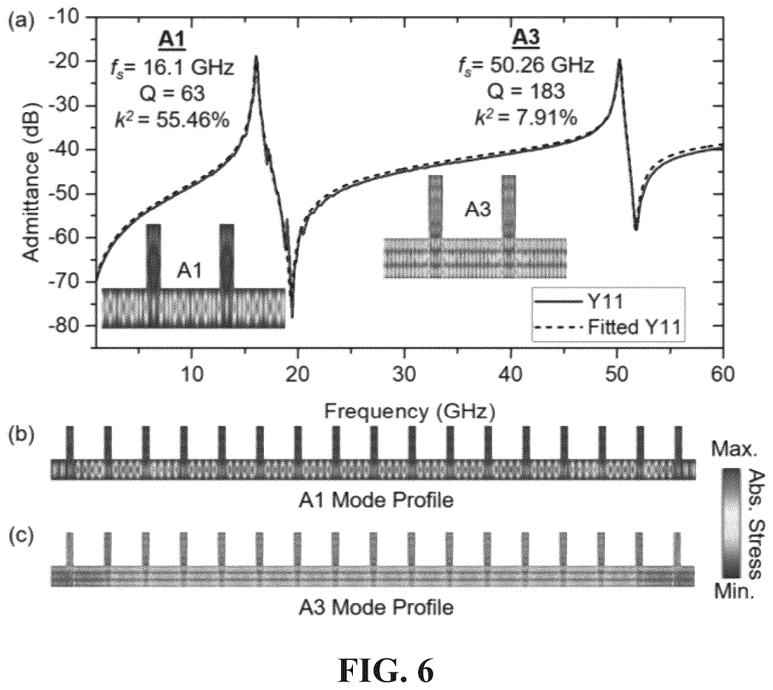

FIG. 6 shows, for a second example prototype, experimental results for a 2-layer acoustic resonator and features thereof. FIG. 6 shows the admittance and the A1 mode and A3 mode (i.e., stress) profiles of the exemplary 2-layer acoustic resonator using COMSOL FEA simulation. In FIG. 6, subpanel (a) shows the simulated admittance of the exemplary 2-layer acoustic resonator. As shown in subpanel (a), the A1 tone was 16.1 GHz with a Q of 85 and k² of 58.2%, and the A3 tone was 50.26 GHz with a Q of 251 and k² of 7.7%.

In FIG. 6, subpanels (b) and (c) show the simulated mode (i.e., stress) profiles for the A1 and A3 tones respectively. As shown in subpanels (b) and (c), the stress profiles for the A1 and A3 tones were well-defined and well-constrained between the electrodes. The resonator parameters were optimized for the A3 tone, resulting in degraded A1 performance. However, the exemplary 2-layer acoustic resonator still showed large k² at both tones.

Simulated 3-layer acoustic resonator. The study simulated the exemplary 3-layer acoustic resonator (details in FIG. 2C and Table 3) using COMSOL FEA simulation from 1 to 50 GHz. The study assumed equal layer thicknesses for the LiNbO₃ layers and did not include capacitive feedthrough. Additionally, the study assumed a material Q of 1000 for the extraction of k² and identification of spurious modes. In this case, the study calculated k² as shown in Equation 1.

$${k}^{2} = \frac{{π}^{2}}{8} ( {( \frac{{f}_{p}}{{f}_{s}} )}^{2} - 1 ) \qquad ( Eq . l )$$

In Equation 1, fₛ is the series resonant peak (i.e., frequency shift, shift in resonance) and fₚ is the parallel peak (also referred to as parallel resonance, parallel peak, and shunt resonance).

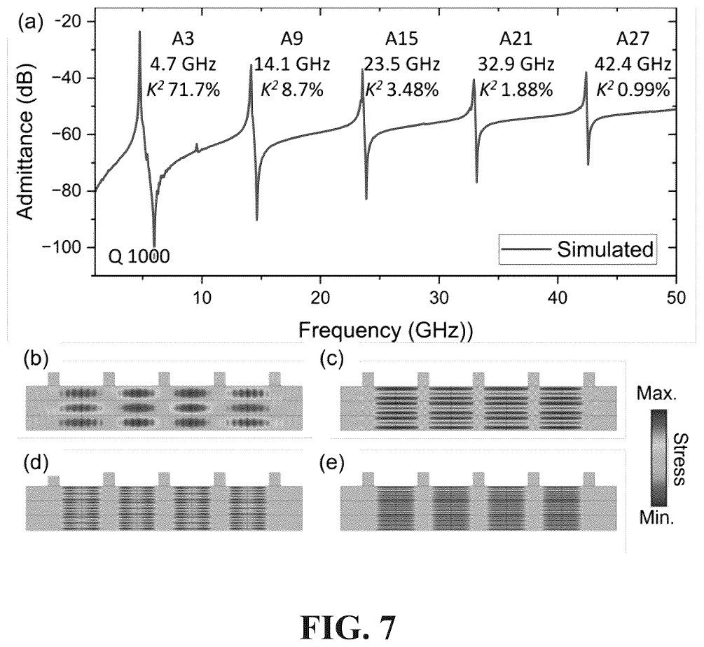

FIG. 7 shows, for a third example prototype, experimental results for a 3-layer acoustic resonator. FIG. 7 shows the admittance and mode (i.e., stress) profiles of the exemplary 3-layer acoustic resonator using COMSOL FEA simulation.

As shown in FIG. 7, subpanel (a), the simulation showed strong, largely spurious free resonances up to 45 GHz. The resultant k² of the fundamental A3 mode supported by the exemplary 3-layer acoustic resonator was 71.7%. The following A9, A15, A21, and A27 modes showed diminishing k², consistent with the expected reduction in coupling for the individual layers of the periodically poled piezoelectric (P3F) film layer given by Equation 2.

$${k}_{m}^{2} \approx \frac{{k}_{A 1}^{2}}{{m}^{2}} \qquad ( Eq . 2 )$$

In Equation 2, kₘ² is the coupling of the m^{th} mode in a single P3F layer and k_{A1}² is the coupling of the A1 mode in a single layer of the P3F film, following from the approximation for an individual layer stack [19″]. Since the study assumed the layer thicknesses to be equal, intermediate modes did not have significant coupling and were effectively suppressed. In FIG. 7, subpanels (b)-(e) show the mode profiles of the associated tones for the A3 through A21 modes. As shown in subpanels (b)-(e), the modes were confined to the region between the electrodes, with each layer supporting one-third of the total stress profile present in the piezoelectric film layer.

Simulated 1-layer-resonator-based filter. The study integrated three 1-layer acoustic resonators into a mmWave filter. The first 1-layer acoustic resonator was employed as a series resonator, while the second and the third 1-layer acoustic resonators were employed as shunt resonators. The study referred to this filter as a first 1-layer-resonator-based filter.

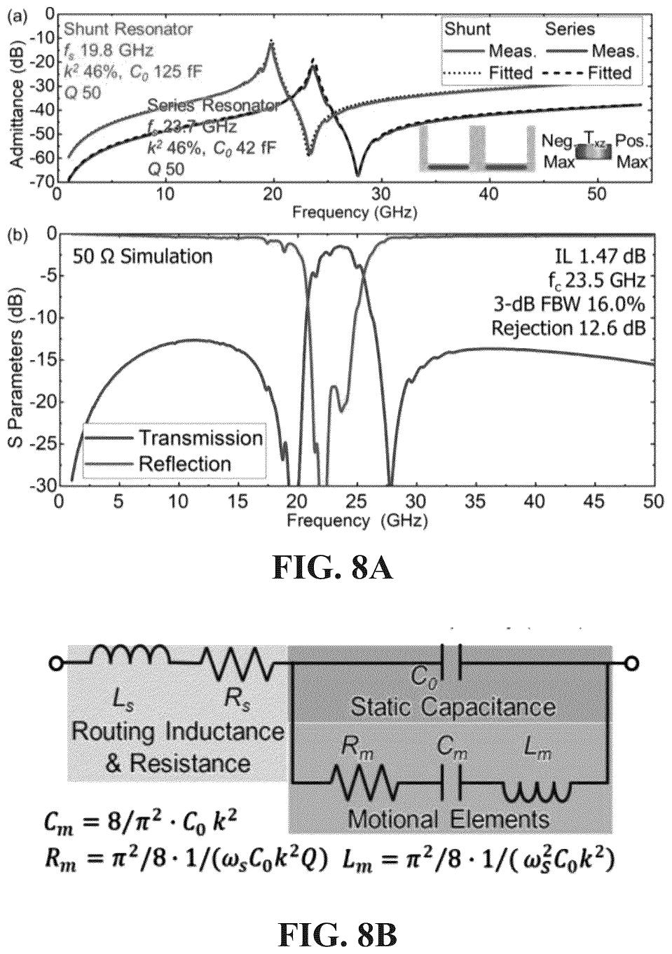

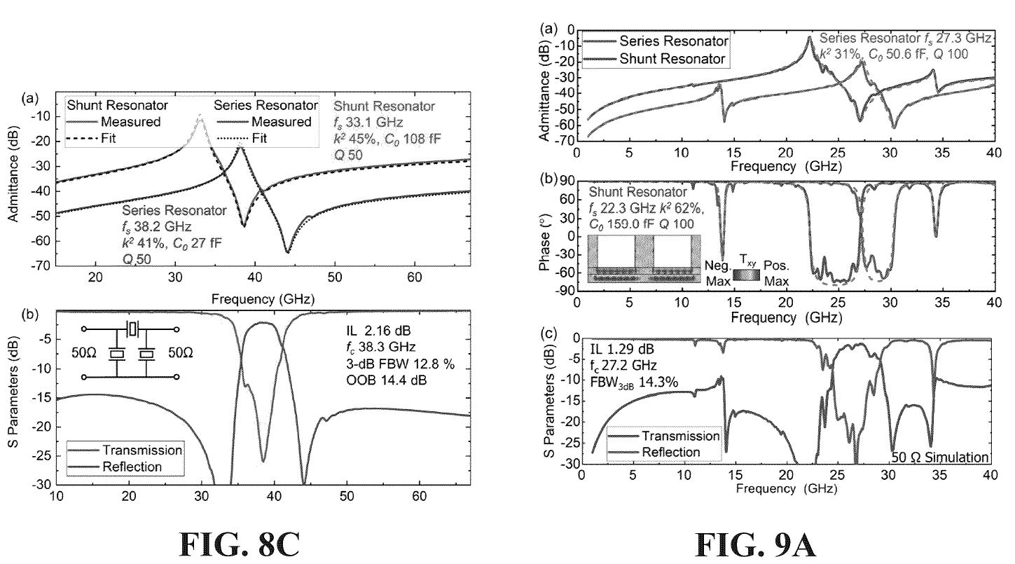

FIGS. 8A-8C show, for a fourth example prototype, experimental results for a 1-layer-resonator-based filter.

Each 1-layer acoustic resonator employed in the first 1-layer-resonator-based filter comprised interdigital transducers (IDT) (i.e., independently addressable microelectrode arrays) on top of a 128° Y-cut LiNbO₃ thin-film, suspended over a silicon (Si) substrate with 1 μm thick a-Si bonding (i.e., sacrificial) layer. The study selected Si for easier structure release. The electric field between IDTs excited the A1 mode through the e₁₅ piezoelectric coefficient.

The study simulated the first 1-layer-resonator-based filter using the COMSOL FEA simulation. FIG. 8A shows simulated A1 resonator admittance (in subpanel a) and filter response (in Subpanel b) of the 1-layer-resonator-based filter.

As shown in FIG. 8A, subpanel (a), the simulated A1 resonator admittance shows high k² of 46%. The study developed series and shunt resonators with different film thicknesses (more specifically, 75 nm for series and 90 nm for shunt) to achieve the necessary shift in resonance (fₛ) for the 23.5 GHz bandpass filter. The static capacitance C₀ was set for impedance matching to 50Ω while providing more than 12 dB out-of-band (OoB) rejection. The study assumed Q to be 50 from earlier results.

The study then imported the simulated resonator admittance into Keysight Advance Design System for filter synthesis. Subpanel (b) shows an insertion loss (IL) of 1.47 dB, a center frequency (f_{c}) of 23.5 GHz, a 3-dB fractional bandwidth (FBW) of 16%, and an out-of-band (OoB) rejection of 12.6 dB for the simulated filter. The low-loss and wideband filter response validated the promising perspective of the thin-film LiNbO₃ platform at mmWave.

The study also developed a second 1-layer-resonator-based filter (i.e., third-order ladder filter) employing three 1-layer acoustic resonators that had a different set of geometric parameters.

The 1-layer acoustic resonators were laterally excited devices using IDT's to excite e₁₅ of a 128° Y-cut LiNbO₃ piezoelectric layer. The full material stack consisted of thin-film LiNbO₃ on over 1 μm amorphous silicon (a-Si), used for bonding and sacrificial purposes, on top of a 500 μm silicon carrier substrate. The spacing between adjacent IDT's was 3 μm and aluminum was selected as the metal layer since it had good selectivity during silicon etching and resonator release.

The study simulated the second 1-layer-resonator-based filter using the COMSOL FEA simulation. FIG. 8B shows the modified Butterworth-Van Dyke (MBVD) model configured to extract geometric parameters of an acoustic resonator (e.g., series and shunt resonators). FIG. 8C shows the simulated A1 resonator admittance (in subpanel a) and filter response (in subpanel b), of the second 1-layer-resonator-based filter.

The study extracted the electromechanical coupling (k²) of the second 1-layer-resonator-based filter using the modified Butterworth-Van Dyke (MBVD) fitting shown in FIG. 8B, approximated by Equation 1. The MBVD model did not include the EM resonances expected to occur around 50 GHz and the associated frequency shifts (i.e., shifts in resonance) incurred on the resonator, experimentally observed in a previous study on 22 GHz filters [73].

As shown in FIG. 8C, subpanel (a), the simulated results showed series resonances (fₛ) at 33 and 38 GHz, with k² of 45 and 41% for the shunt and series resonators, respectively, well suited for the frequency range 2 (FR2) band. The difference in k² arose from the thickness variation between resonators, 53 nm shunt, and 46 nm series, required to synthesize the ladder filter.

The study chose the static capacitances so as to achieve minimum IL with 50Ω port impedances. The study exported and used the simulated FEA data to synthesize and simulate the filter with the aid of the Cadence Air-Worthiness-Release (AWR) platform. As shown in subpanel (b), the passband was centered at 38.3 GHz, with an insertion loss (IL) of 2.16 dB, 12.8% fractional bandwidth (FBW), and an out-of-band rejection of 14.4 dB.

Simulated 2-layer-resonator-based filter. The study integrated three 2-layer acoustic resonators into a mmWave filter. The first 2-layer acoustic resonator was employed as a series resonator, while the second and the third 2-layer acoustic resonators were employed as shunt resonators. The study referred to this filter as a 2-layer-resonator-based filter.

Each 2-layer acoustic resonator comprises 350 nm thick aluminum (Al) interdigital transducers (IDT) (i.e., independently addressable microelectrode arrays) on the top of 150 nm thick bi-layer (i.e., 2 layers) 128. Y-cut LiNbO₃ thin film, suspended over a sapphire substrate with 1 μm thick a-Si bonding and sacrificial layer. The a-Si layer helped preserve the quality of the transferred thin film [73″]. The alternating lateral electrical fields between IDTs excited the second-order symmetric (S2) mode via the piezoelectric coefficient e₁₅ in 128° Y-cut LiNbO3. The thick electrodes on the top reduced the resistive loss and thermal resistance while not mechanically loading the resonance as it was in the stress nodes [73″]. The study fully anchored the 2-layer acoustic resonators for higher structural strength during the release.

The periodically poled piezoelectric (P3F) LiNbO₃ stack (i.e., layer) for filters, wherein piezoelectric thin films with opposite orientations, rotated about the axis defined by the intersection of the plane joining the two layers, were placed on top of each other, enabling higher-order mode operation in thicker films without losing electromechanical coupling (k²) [43″], [52″], [74″], [75″], [76″], [77″]. Specifically, the thickness of each layer matched the half wavelength in the higher-order thickness modes. Thus, piezoelectrically generated charges build up and may be effectively picked up by a single transducer on the top of the P3F stack.

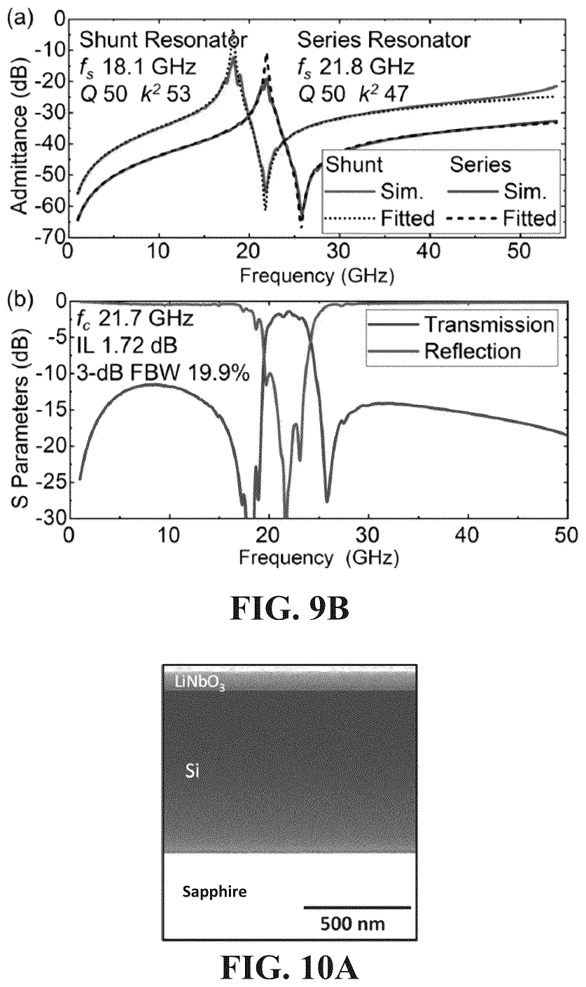

FIG. 9A shows the admittance (in subpanel a), phase (in subpanel b), and filter response (in subpanel c) of the 2-layer-resonator-based filter using COMSOL FEA simulation. In the example shown in FIG. 9A, subpanels (a) and (b), the COMSOL FEA simulated S2 resonator admittance shows a high k² of 62% for the shunt resonator at 22.3 GHz and k² of 31% for the series resonator at 27.3 GHz. This was obtained via a modified Butterworth-Van Dyke (MBVD) fitting with multiple motional branches shown in FIG. 5C [78″]. The study ignored series inductor Lₛ and resistors Rₛ for FEA, as the EM effects were not coupled in COMSOL. The study developed series and shunt resonators with different film thicknesses (more specifically, 45 nm on top, 85 nm on bottom for series, and 75 nm on top, 85 nm on bottom for shunt) to achieve the necessary shift in resonance (fₛ) [79″]. The static capacitance C₀ was chosen to match the impedance of the filter to 50Ω while providing 10 dB out-of-band (OoB) rejection. The resonator Q was assumed to be 100 conservatively, which was lower than the previous LiNbO₃ P3F [76″]. Subpanel (c) shows the simulated filter response with an insertion loss (IL) of 1.29 dB, a center frequency (f_{c}) of 27.2 GHz, a 3-dB fractional bandwidth (FBW) of 14.3%, and an out-of-band (OoB) rejection of 10.1 dB. The low-loss and wideband response promise mm Wave compact filter platform using P3F LiNbO₃.

Simulated of Al₂O₃/Si-based filter. The study integrated three Al₂O₃/Si-based acoustic resonators into a mmWave filter. The first Al₂O₃/Si-based acoustic resonator was employed as a series resonator, while the second and the third Al₂O₃/Si-based acoustic resonators were employed as shunt resonators. The study referred to this filter as an Al₂O₃/Si-based filter.

The active region of each Al₂O₃/Si-based acoustic resonator of interdigitated transducers (IDT) (i.e., independently addressable microelectrode arrays) on a thin-film LiNbO₃ piezoelectric layer. Thickness-shear waves, i.e., first-order antisymmetric (A1) mode, were excited via the e₁₅ piezoelectric coefficient by the electrodes. The study selected aluminum for the metal layer with a thickness of 350 μm, and the spacing between electrodes was 3 μm, following the guidelines reported in [105]. The design approach was identical for both Si and Al₂O₃ carrier substrates, as the resonators were released and only connected with the substrate with anchors.

FIG. 9B shows the admittance (in subpanel a) and filter response (in subpanel b) of the Al₂O₃/Si-based filter using COMSOL FEA simulation.

As shown in subpanel (a), the results showed a frequency shift (i.e., shift in resonance), which was necessary for filter synthesis, where the parallel resonance (fₚ) of the shunt resonator and the series resonance (fₛ) of the series resonator were intended to overlap. The study achieved the frequency shift using different thicknesses of LiNbO₃ for the shunt and series resonators, respectively. Q was set as 50, and k₂ was extracted as Equation 1 from a fitting using the modified Butterworth-Van Dyke (MBVD) model shown in FIG. 8B [107]. The study selected the values of C₀ to obtain minimum insertion loss (IL) in a 50Ω Al₂O₃/Si-based filter.

The study exported the obtained admittance for the shunt and series resonators into a circuit simulator to assess the expected performance of the filter (i.e., filter response). Subpanel (b) shows the simulated frequency response of the Al₂O₃/Si-based filter. As shown in subpanel (b), the filter response was centered at 21.7 GHz with insertion loss (IL) of 1.72 dB and a 19.9% fractional bandwidth (FBW), promising performance at this frequency range.

### Fabricated Acoustic Resonators and Filters

Fabricated 1-layer acoustic resonator. The study purchased and performed material-level analysis on a LiNbO₃—Si-sapphire stack by generating cross-sectional scanning electron microscopy (SEM) images in an FEI Nova 600 DualBeam focused ion beam system.

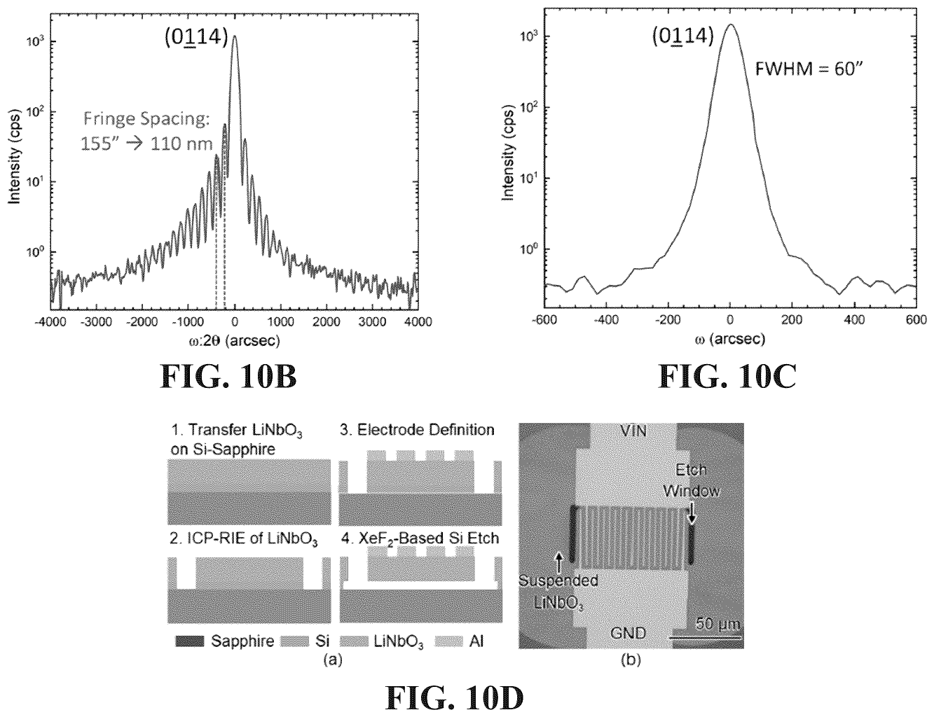

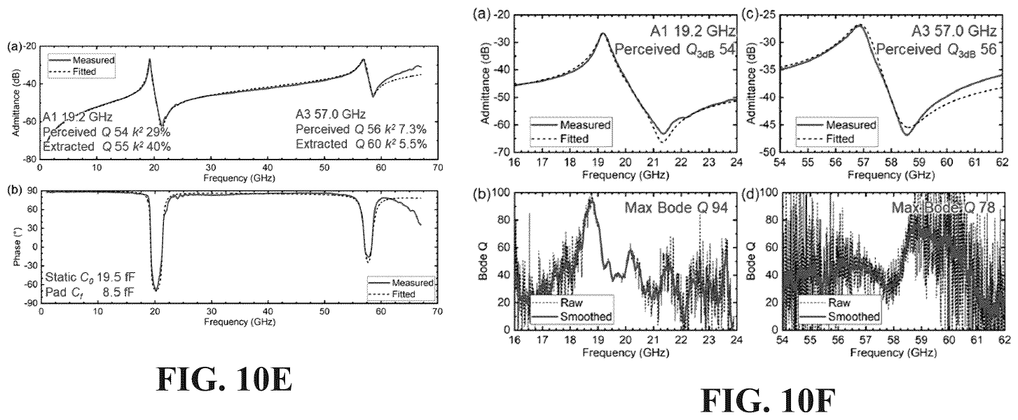

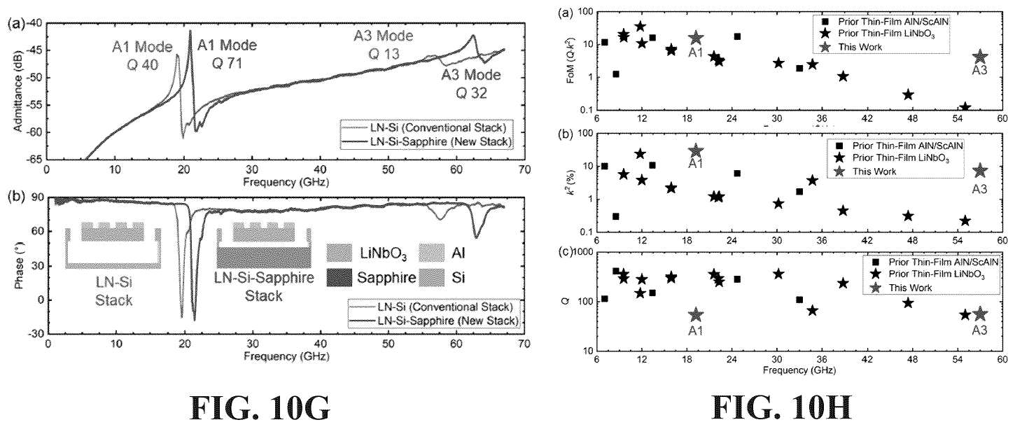

FIGS. 10A-10G shows, for the first example prototype, additional experimental results for a 1-layer acoustic resonator and features thereof. FIG. 10A shows the SEM image of the LiNbO₃—Si-sapphire stack. As shown in FIG. 10A, the thickness of the LiNbO₃ layer was approximately 110 nm on top of the deposited Si layer on the sapphire. The study also employed triple-axis X-ray diffraction (XRD) measurements to structurally characterize the LiNbO₃ film.

FIG. 10B shows an example symmetric ω:2θ of the (0114) reflection on the LiNbO₃ film. As shown in FIG. 10B, the study observed thickness fringes corresponding to an approximate 110 nm-thick layer, consistent with the cross-sectional SEM image shown in FIG. 10A. The presence of fringes was also indicative of a high-quality interface between the LiNbO₃|Si interface. Furthermore, FIG. 10C shows the symmetric (0114) XRD rocking curve of the LiNbO₃ layer having a full width at half maximum (FWHM) of about 60 arcsec, which was superior to previously available LiNbO₃ transferred layers on silicon [3].

FIG. 10D shows the fabrication process of the 1-layer acoustic resonator. Specifically, as shown in subpanel (a), the study etched the etch window via plasma etch and added Al electrodes on top of the LiNbO₃. Finally, the study released the 1-layer acoustic resonator via XeF₂-based Si etch. Subpanel (b) shows the optical image of the fabricated 1-layer acoustic resonator.

The study fabricated the 1-layer acoustic resonator (referred to as a fabricated 1-layer acoustic resonator) on a testbed with the same design, just without IDTs, for extracting the pad feedthrough capacitance (C_{f}) and resistance (R_{f}). The study measured the fabricated 1-layer acoustic resonator with a Keysight network analyzer in the air at room temperature.

FIG. 10E shows the measurement values of the amplitude and phase of the admittance of the fabricated 1-layer acoustic resonator, respectively, without de-embedding. As shown in subpanel (a), the study obtained A1 at 19.2 GHz and A3 at 57.0 GHz. The perceived 3-dB Q at the series resonances (fₛ) were 54 for A1 and 56 for A3. The perceived k², defined by fₛ and shunt resonances (fₚ) as k_{perceived}²=((fₚ/fₛ)²−1)·π²/8, were 29% for Al and 7.3% for A3.

As the study did not consider pad feedthrough, the measured k_{perceived}² of A1 was slightly lower than the simulated k_{perceived}² of A1 expected in the FEA simulation (shown in Table 4). In subpanel (a), k_{perceived}² of A3 was higher because the series inductance of the IDTs (captured by Lₛ) stored more energy in the electromagnetic (EM) domain while also introducing more loss. The study achieved a figure of merit (FoM) Q·k² of 15.7 and 4.1 at 19.2 GHz and 57.0 GHz, respectively, for the A1 and A3 tones.

FIG. 10F shows zoomed-in admittance and Bode Q of A1 and A3. The study extracted maximum bode Q of 94 and 78 from A1 and A3. Maximum bode Q of 94 and 78 (shown in Subpanels b and d, respectively) were higher than 3-dB Q (also referred to as Perceived Q3 dB) of 54 and 56 (shown in subpanels a and c, respectively) for both A1 and A3, implying that further Q enhancement feasible via anchor optimization and electrical loss reduction.

The study used the BVD model (shown in FIG. 5C) to extract Q and k² without EM effects in the probing pads and IDTs. The static capacitance C₀ was 19.5 fF slightly higher than FEA due to the higher dielectric constant in sapphire. Feedthrough capacitance (C_{f}) was 8.5 fF, and feedthrough resistance (R_{f}) was 100Ω, both extracted from the fabricated 1-layer acoustic resonator. The side length (Lₛ) of the fabricated 1-layer acoustic resonator was 0.1 nH, extracted from the self-resonance shown in subpanel (b) of FIG. 10E.

As shown in Table 4, the study obtained the extracted k² for A1 (referred to as Extracted k_{A1}²) at 40% and the extracted k² for A3 (referred to as Extracted k_{A3}²) at 5.5% from the fabricated 1-layer acoustic resonator, which were comparable to the extracted k² for A1 and A3 from the FEA simulated results shown in FIG. 5A.

The study compared the new LiNbO₃—Si-Sapphire stack with the conventional LiNbO₃—Si stack. Using the same testbed design with Λ of 15 μm, L_{g} of 4.5 μm, Lₑ of 3 μm, and Wₐ of 22 μm, the study compared the measured admittance and phase of the LiNbO₃—Si-Sapphire stack with the conventional LiNbO₃—Si stack as shown in FIG. 10G. In FIG. 10G, subpanels (a) and (b), both A1 and A3 in the new stack showed much improved Qₛ at mmWave, validating the superior EM properties in sapphire.

Additionally, the study compared extracted FOM, k², and Q, of the fabricated 1-layer acoustic resonator with the SoA resonator shown in FIG. 10H. For A3, the FoM of the fabricated 1-layer acoustic resonator was improved over an order of magnitude compared to SoA resonators at 60 GHz (shown in subpanel a), while the operating frequency was doubled compared to SoA devices with a similar FoM.

Fabricated 2-layer acoustic resonator. The study received the film stack and performed a film stack characterization on a wafer edge piece prior to fabrication.

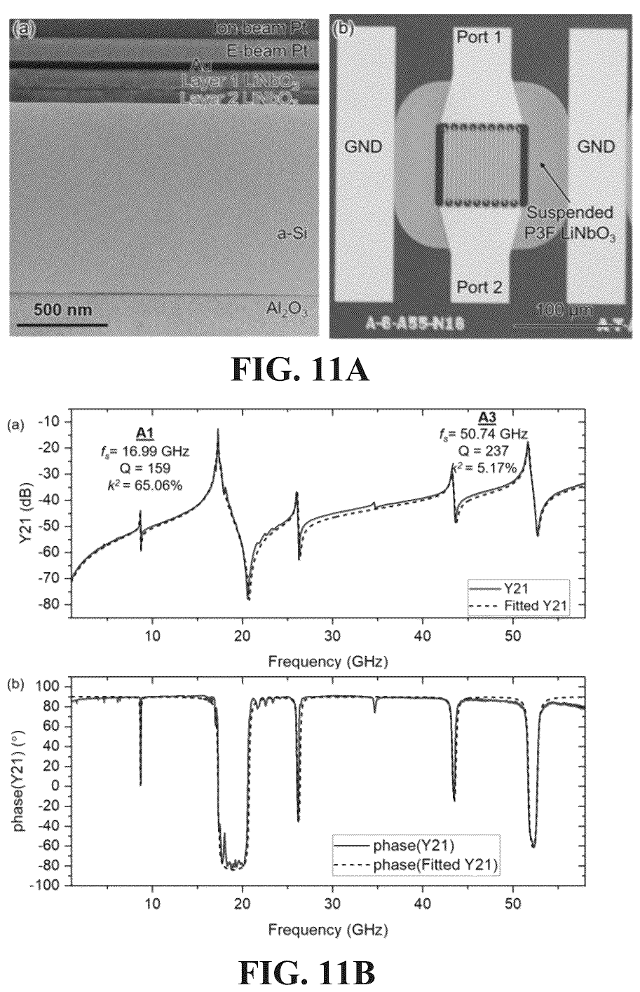

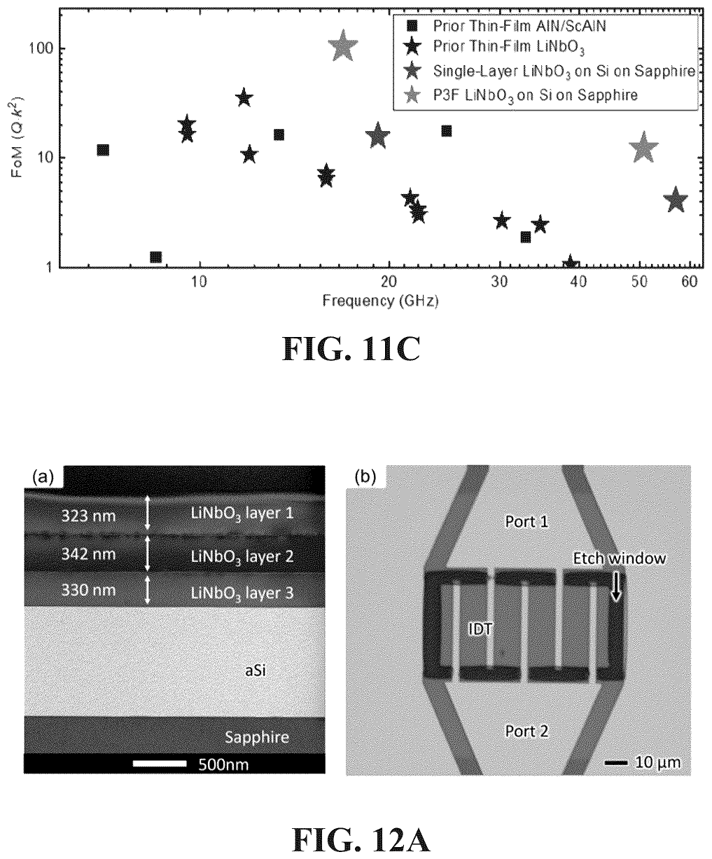

FIGS. 11A-11C, for the second example prototype, additional experimental results for a 2-layer acoustic resonator and features thereof. In FIG. 11A, subpanel (a) shows the transmission electron microscope (TEM) cross-sectional image of the film stack. As shown in subpanel (a), TEM showed variation in the film thicknesses between the two LiNbO₃ layers (e.g., Layer 1 LiNbO₃ and Layer 2 LiNbO₃), which was expected to contribute to spurious mode responses away from the two primary design resonances shown in the simulation. Using the TEM, the study measured the first layer thickness to be 105 nm and the second layer to be 80 nm. However, due to variation across the wafer, the actual layer thickness was expected to be slightly different for the portion of the wafer used for the fabrication.

First, the study etched the two layers of LiNbO₃ via ion milling. Then, the study patterned the 350 nm thick aluminum (Al) electrode and busline features using e-beam lithography and deposition. Finally, the study released the LiNbO₃ from the substrate with a xenon difluoride (XeF₂) based isotropic etch. This facilitated the mechanical isolation of the resonator from the substrate, reducing mechanical losses. In FIG. 11A, subpanel (b) shows the optical image of a fabricated 2-layer acoustic resonator.

FIG. 11B shows the measured admittance (in subpanel a) and phase curves (in subpanel b) of the fabricated 2-layer acoustic resonator. The study fitted the data using a five-motional branch modified Butterworth Van-Dyke model shown in FIG. 8B, which allowed for the fitting of the two primary A1 and A3 tones as well as three main spurious modes. In subpanels (a) and (b), the fabricated 2-layer acoustic resonator demonstrated a 3-dB Q of 159 and k² of 65.06% for the 16.99 GHz A1 tones and a 3-db Q of 237 and k² of 5.17% for the 50.74 GHz A3 tone. The resultant FoM for the A1 and A3 tones were 103.4 and 12.2, respectively. The data shown and performance metrics both used raw data without any de-embedding. FIG. 11C compares the Figure of Merit (FoM, Qk²) of the fabricated 2-layer acoustic resonator and the SoA resonator. The fabricated 2-layer resonator outperformed the current state-of-the-art (SoA) resonators at corresponding frequencies.

Fabricated 3-layer acoustic resonator. The study purchased and performed a film stack characterization on the bonded periodically poled piezoelectric (P3F) film stack.

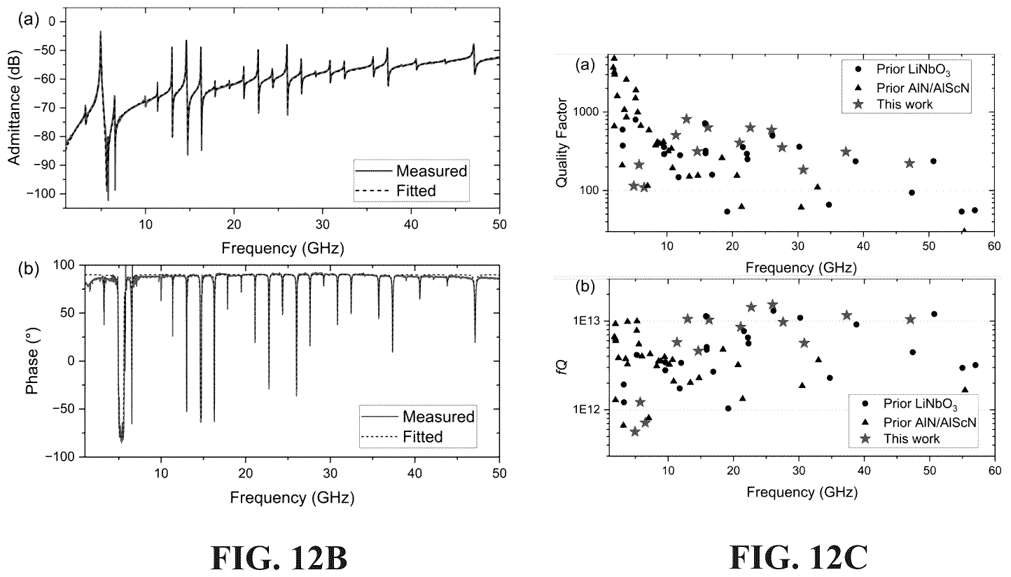

FIGS. 12A-12C, for the third example prototype, additional experimental results for the 3-layer acoustic resonator and features thereof. FIG. 12A shows the bright field scanning transmission scanning electron microscopy (BF STEM) image of the cross-section of the film stack from a sample near the wafer edge (in subpanel a) and an optical image of the fabricated 3-layer acoustic resonator (in subpanel b). As shown in subpanel (a), the BF STEM image showed LiNbO₃ layers slightly thinner than the target 370 nm and with thickness variation between layers on the order of ±10 nm for the region examined.

Subpanel (b) shows the optical image of the fabricated 3-layer acoustic resonator. The fabrication process started when the study first defined the active region of the 3-layer acoustic resonator through maskless optical lithography and etching. Then, the study patterned the electrode and busline features using e-beam lithography and lift-off. Finally, the study released the thin film from the substrate using XeF₂.

The study then measured the fabricated 3-layer acoustic resonator using a vector network analyzer to 50 GHz and extracted the associated admittance parameters of the fabricated 3-layer acoustic resonator. Due to the variation in film thickness, many more modes were present than in the simulation. This was due to the excitation of independent layers of the P3F stack being excited at slightly different frequencies, resulting in the intermediate modes receiving some coupling, which further reduces the coupling of the primary modes as well, resulting in a large decrease compared to the simulated coupling values. The study then fitted the measured admittance, and phase data using a 26-motional branch modified Butterworth Van-Dyke model (MBVD) (not shown). FIG. 12B shows the raw and fitted measured response (e.g., admittance in subpanel a, phase in subpanel b) of the fabricated 3-layer acoustic resonator.

For extraction of geometric parameters associated with the prominent peaks, the study used an automated code on the raw admittance data to find resonances, their k² and series 3 dB-Q. Table 5 shows the extracted resonance data from the fabricated 3-layer acoustic resonator.

TABLE 5

| Resonance | fₛ (GHz) | fₚ (GHz) | k_{eff}² | Qₛ |
|---|---|---|---|---|
| 1 | 4.9402 | 5.6490 | 37.90% | 114.356 |
| 2 | 6.5116 | 6.5728 | 2.32% | 109.622 |
| 3 | 11.360 | 11.371 | 0.24% | 507.142 |
| 4 | 12.988 | 13.043 | 1.03% | 811.800 |
| 5 | 14.616 | 14.776 | 2.71% | 315.000 |
| 6 | 16.257 | 16.334 | 1.16% | 635.062 |
| 7 | 21.094 | 21.122 | 0.32% | 405.653 |
| 8 | 22.724 | 22.778 | 0.58% | 631.222 |
| 9 | 25.976 | 26.046 | 0.66% | 590.363 |
| 10 | 27.582 | 27.628 | 0.41% | 353.615 |
| 11 | 30.824 | 30.870 | 0.36% | 183.476 |
| 12 | 37.320 | 37.404 | 0.55% | 311.000 |
| 13 | 47.052 | 47.180 | 0.67% | 221.943 |

As shown in Table 5, high series peak quality factored up to 811 at 12.98 GHz was observed. FIG. 12C compares the quality factor Q (in subpanel a) and the frequency×quality factor product (fQ) (in subpanel b) of the fabricated 3-layer acoustic resonator and the SoA acoustic resonators (e.g., AlN, AIScN, prior LiNbO₃).

As shown in subpanel (a), the results from the fabricated 3-layer acoustic resonator were comparable, or even exceeding, many of the highest quality factors observed in SoA acoustic filters. When the study normalized performance versus frequency by use of the fQ product, the fabricated 3-layer acoustic resonator showed high performance for the higher-order resonances. This is shown in subpanel (b) with the resonances showing better than 10¹³ fQ product for a majority of extracted tones above 10 GHz. The result further demonstrated the promise of employing suspended P3F to realize high-performance mm-Wave acoustic devices for next-generation communication.

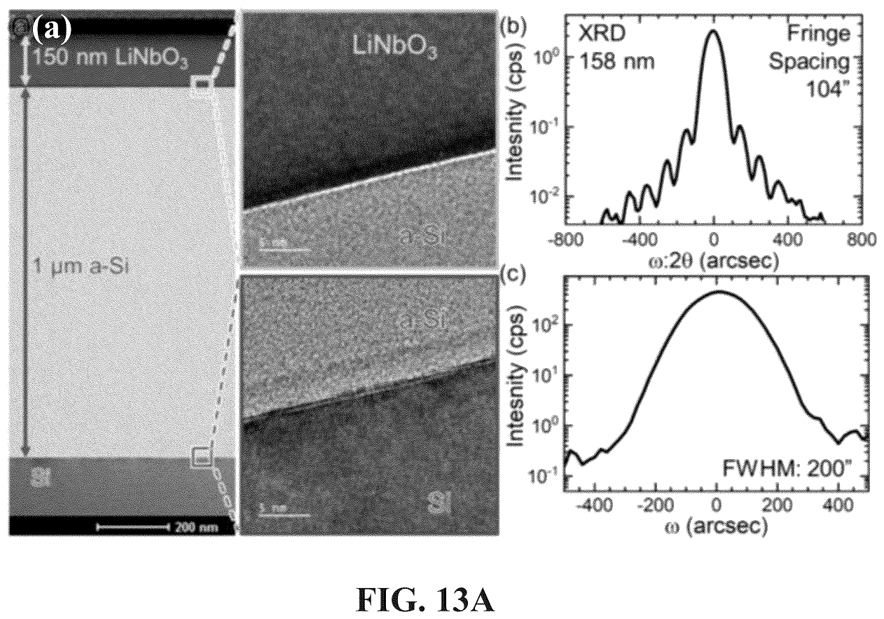

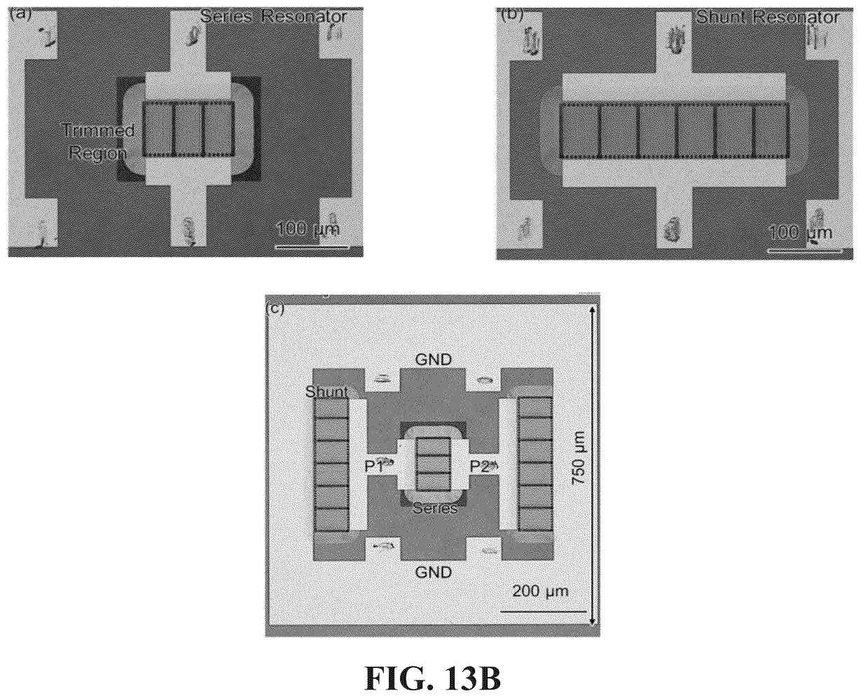

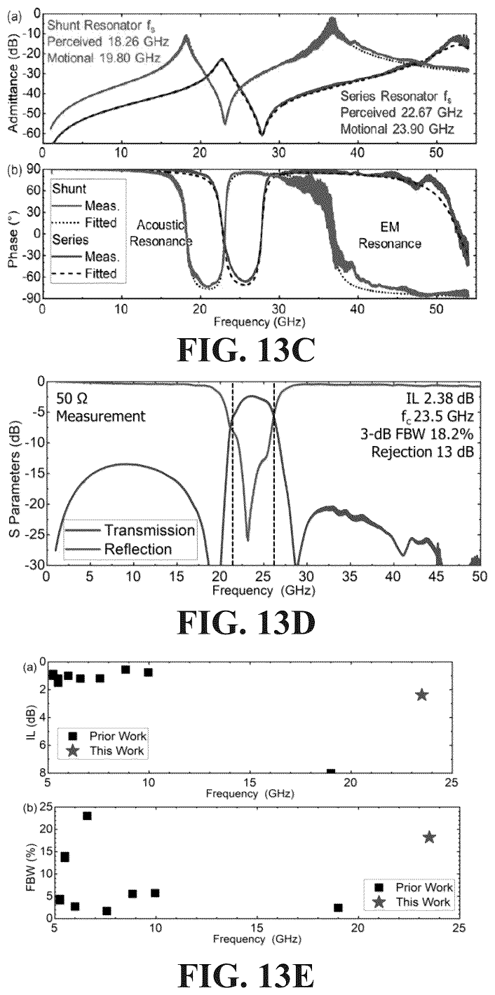

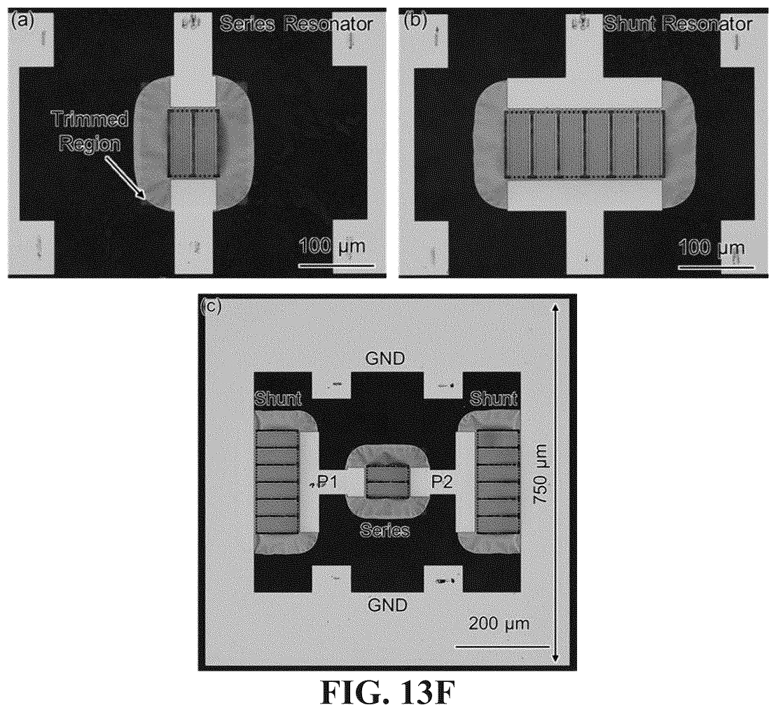

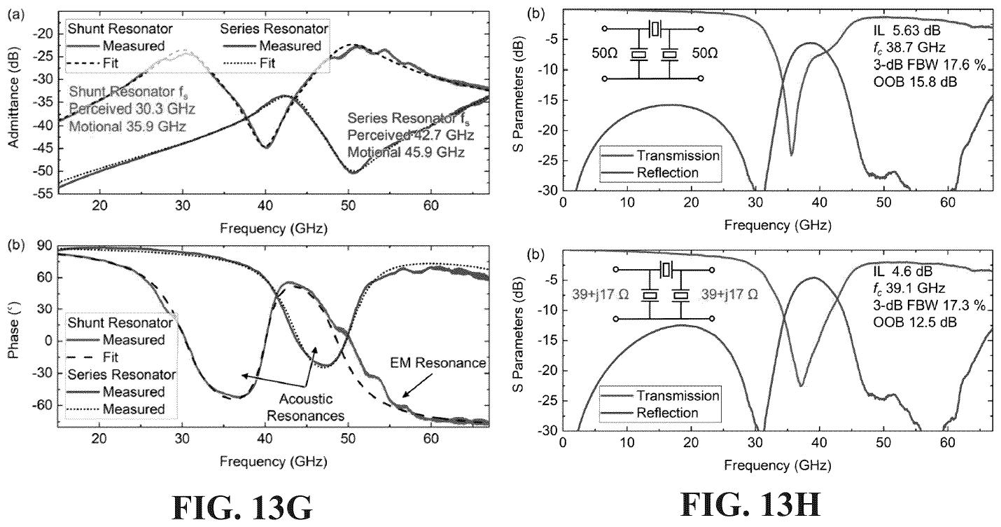

First fabricated 1-layer-resonator-based filter. The study purchased and validated the thickness of the resonator stack (LiNbO₃-aSi-Si) using transmission electron microscopy (TEM) imaging. FIGS. 13A-13H shows, for the fourth example prototype, additional experimental results for the 1-layer-resonator-based filter and features thereof. FIG. 13A shows the cross-sectional TEM image of the resonator stack (in subpanel a) and the X-ray diffraction (XRD) symmetric reflection of the piezoelectric layer (in subpanel b).

As shown in subpanel (a), the thickness of the LiNbO₃ layer was around 150 nm, and the bonding a-Si layer (i.e., sacrificial layer) is 1 μm. Good interfaces between LiNbO₃, a-Si, and Si were observed. Next, the study carried out a more quantitative material analysis using X-ray diffraction (XRD). Subpanels (b) and (c) show the plots of the symmetric ω:2θ of (0114), and the triple-axis diffractometry (TAD) rocking curve of the piezoelectric layer, respectively. The XRD measured a thickness of 158 nm of the LiNbO3 layer, revealing slight thickness variation across the sample. A full width at half maximum (FWHM) of 200″ from the rocking curve with Si substrate was slightly worse than the FWHM from the rocking curve with the sapphire substrate [45] but significantly improved from the FWHM from the rocking curve without a-Si [49], corroborating the stack choice.

The fabrication process initiated by trimming down the LiNbO₃ layer to 90 nm (the thickness of the shunt resonators) over the entire sample. This was accomplished using ion beam-assisted argon gas cluster trimming, which maintain surface roughness and crystallinity [50]. Next, the study defined and etched release windows by ion milling. Afterward, the study performed another trimming to 75 nm over selected regions for series resonators, providing the required frequency shift (fₛ). Finally, the study patterned metal electrodes and released the resonators through xeon difluoride (XeF₂) Si etch.

The study then integrated three fabricated 1-layer acoustic resonators into a mmWave filter, generating a first fabricated 1-layer-resonator-based filter. The first fabricated 1-layer acoustic resonator was employed as a series resonator, while the second and the third fabricated 1-layer acoustic resonators were employed as shunt resonators.

FIG. 13B shows the optical images of the first fabricated 1-layer-resonator-based filter comprising a series resonator and two shunt resonators, wherein each series and shunt resonator was a fabricated 1-layer acoustic resonator. Specifically, subpanel (a) shows the optical image of a fabricated 1-layer series resonator, subpanel (b) shows the optical image of a fabricated 1-layer shunt resonator, and subpanel (c) shows the optical image of the first fabricated 1-layer-resonator-based filter comprising one series resonator and two shunt resonators.

Table 6 shows the geometric parameters of each fabricated series resonator and shunt resonator in the first fabricated 1-layer-resonator-based filter. The filter had a small footprint of 0.75 mm by 0.74 mm, including the ground traces.

TABLE 6

| Symbol | Parameter | Series | Shunt |
|---|---|---|---|
| Λ | Cell length (μm) | 6 | 6 |
| Lₑ | Electrode length (μm) | 0.8 | 0.8 |
| L_{g} | Gap length (μm) | 2.2 | 2.2 |
| N | Number of electrode pairs | 15 | 41 |
| Wₐ | Aperture width (μm) | 69 | 69 |
| Wᵣ | Recessed width (μm) | 5 | 5 |
| T_{LN} | LiNbO₃ thickness (nm) | 75 | 90 |
| T_{Al} | Aluminum thickness (nm) | 350 | 350 |
| T_{a-Si} | Sacrificial a-Si thickness (nm) | 1 | 1 |

The study measured the fabricated resonators and filters using a Keysight vector network analyzer (VNA) in the air at a −15 dBm power level. As shown in FIG. 13C, subpanel (a) and (b) show the admittance and phase of the resonators, fitted with the modified Butterworth-Van Dyke (MBVD) circuit model shown in FIG. 8B, respectively. Unlike conventional BVD models, the inductive effects from routing inductance Lₛ were indispensable. More specifically, a higher frequency resonance of electromagnetic (EM) nature is due to the self-resonance of the reactance parasitics embedded in the resonator routing. Routing inductance (Lₛ) and routing resistance (Rₛ) were fitted based on EM resonances. Another effect was that the perceived resonances were at 18.26 GHz for the series and 22.67 GHz for the shunt, which deviated from the mechanical resonances represented by the motional branch elements Lₘ, Cₘ, and Rₘ.

Table 7 shows the scattering parameters (i.e., S-parameters) of the fabricated series and shunt resonators in the first fabricated 1-layer-resonator-based filter.

TABLE 7

| S-parameter | Series | Shunt |
|---|---|---|
| fₛ (GHz) | 23.9 | 19.8 |
| Q | 32 | 40 |
| k² (%) | 43 | 44 |
| C₀ (fF) | 50 | 155 |
| Lₛ (nH) | 0.2 | 0.15 |
| Rₛ (Ω) | 6 | 2 |

As shown in Table 7, the fabricated resonators show high k², around 43%, and Q around 40, matching the simulated FEA results shown in FIG. 8A.

FIG. 13D shows the measured filter response for the first fabricated 1-layer-resonator-based filter. As shown in FIG. 13D, the 23.5 GHz filter exhibited a low insertion loss (IL) of 2.38 dB, wide 3-dB fractional bandwidth (FBW) of 18.2%, and an out-of-band (OoB) rejection of 13 dB, matching the design. As shown in FIG. 13E, compared with the SoA low-loss acoustic filters, the first fabricated 1-layer-resonator-based filter showed unprecedented frequency scaling and FBW enhancement three times higher than previous results.

Second fabricated 1-layer-resonator-based filter. The study fabricated the series and shunt resonators on the LiNbO₃-aSi-Si wafer, wherein the specification thickness of the LiNbO₃ layer was 110 nm.

The fabrication process started when the sample wafer (2.1 by 1.9 cm) was trimmed down using an ion milling etch process to 53 nm to provide the base thickness required by the shunt resonators. The study monitored the desired thickness using a Woollam ellipsometer. Next, the study patterned etching windows using lithography. The study allocated long lateral etch windows along the resonator's length, effectively dividing them into resonator banks, which help the release process. The study performed a second round of ion milling to etch the LiNbO₃ thin film through the etch windows, deep into the a-Si layer. Afterward, the study lithographically defined local trimming regions and carried a third round of ion milling to further trim the thickness of these regions to the target 46 nm. The study used the locally trimmed regions for the series resonators, and they accomplished the frequency shift required to realize the filter. The study verified the step height difference between the base thickness and the local trimmed regions using atomic force microscopy (AFM), and the step height difference was 8±1 nm at different regions on the sample. The study patterned the aluminum electrodes using electron beam lithography (EBL) and metal evaporation. Finally, the study released the resonators using Xeon difluoride (XeF₂) for silicon selective etching.

The study then integrated the fabricated 1-layer series and shunt resonators into an mmWave filter, generating a second fabricated 1-layer-resonator-based filter. FIG. 13F shows the optical images of the fabricated 1-layer series resonator (in subpanel a), the fabricated 1-layer shunt resonator (in subpanel b), and the second fabricated 1-layer-resonator-based filter (in subpanel c).

The study evaluated the performance of the fabricated resonators and filters using a Keysight vector network analyzer (VNA) at a fixed −10 dBm power level. FIG. 13G shows the measured and MBVD-fitted admittance response (in subpanel a) and phase response (in subpanel b) of the fabricated series and shunt resonators, wherein the MBVD model is shown in FIG. 8B. The routing components Lₛ and Rₛ were required to fit the EM resonance embedded in the structure. The measurements showed a small discrepancy in the perceived frequency shift (fs) of the series resonator, which was caused by a slight over-etch of the local region and the interaction with the EM resonance at 50 GHz. The fabricated resonators showed k² of 30 with quality factor Q of 13 for the shunt resonator and k² of 25 with Q of 10 for the series resonator.

In FIG. 13H, subpanel (a) shows measured raw filter data transmission and reflection under 50Ω impedances. As shown in subpanel (a), filter measurements under 50Ω exhibited a passband centered at 38.7 GHz with IL of 5.63 dB, broad 3-dB FBW of 17.6%, and OoB rejection of 15.8 dB. The second fabricated 1-layer-resonator-based filter was the first demonstration of the feasibility of using acoustic technologies for mmWave filters.

To further analyze loss and parasitics in the filter, the measurements showed impedance mismatch from the return loss, deviating from the design. This was due to a combination of factors, including the discrepancy in the perceived frequency response of the resonators, the effects of the EM resonances, as well as higher frequency parasitics embedded in the filter layout. The study then artificially impedance-matched the measurement data in an air-worthiness-release (AWR) model using complex input and output-sourced impedances to predict the filter performance under matched conditions. The results are shown in FIG. 13H, subpanel (b), with 39+j17Ω port impedance. The IL of 4.6 dB, eliminating the port reflection, was the loss in the filter, collectively contributed by the electrical routing loss and mechanical loss. The loss may be further reduced by a series of methods, including using multiple-layer piezoelectric with alternating orientations, so-called periodically poled piezoelectric film (P3F) [74]-[76] to operate at higher-order Lamb modes, thickening up bus lines for less routing resistive loss, and EM-acoustic co-designs for mitigating the inductive parasitics.

Fabricated 2-layer-resonator-based filter. The fabrication process initiated by patterning the resonator regions and then trimming the LiNbO₃ thickness of the active regions to the desired values using ion beam-assisted argon gas cluster trimming to maintain surface roughness and high crystallinity through material analysis [80″]. Next, the study patterned the top electrodes with 350 nm evaporated Al interdigital transducers (IDTs). Additionally, the study thickened the probing pad and routing regions up by another 350 nm evaporated Al to lower the resistive loss. Afterward, the study defined and etched release windows using the ion beam. The study divided the resonator bank into multiple resonators for easier release of the filters. Finally, the study patterned metal electrodes and released the resonators through xenon difluoride (XeF₂) Si etch.

The study then integrated the fabricated 2-layer series and shunt resonators into an mmWave filter, generating a fabricated 2-layer-resonator-based filter.

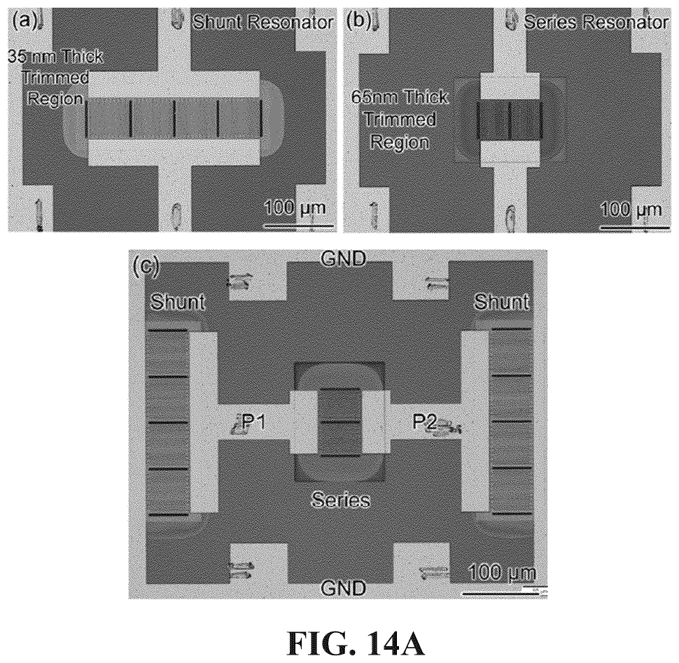

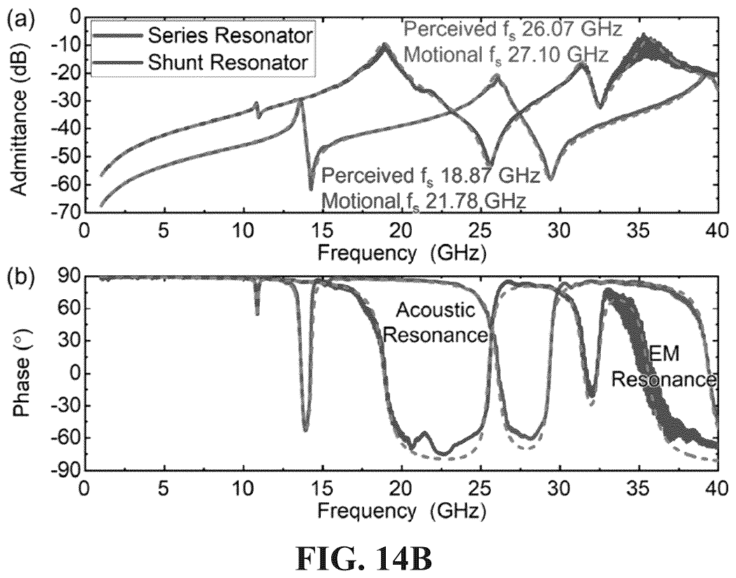

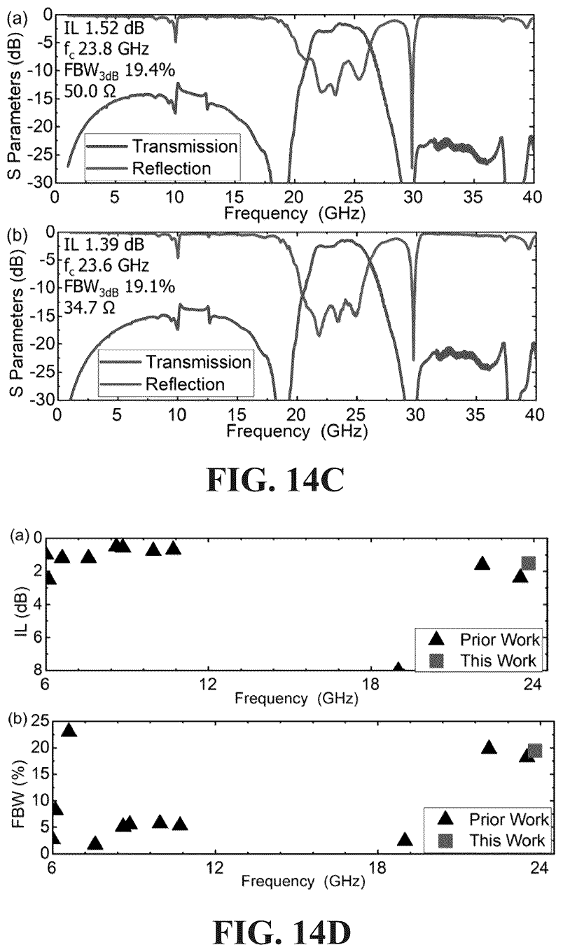

FIGS. 14A-14D shows, for the fifth example prototype, additional experimental results for the 2-layer-resonator-based filter and features thereof. FIG. 14A shows the optical images of the fabricated 2-layer shunt resonator (in subpanel a), the fabricated 2-layer series resonator (in subpanel b), and the fabricated 2-layer-resonator-based filter (in subpanel c). The fabricated 2-layer-resonator-based filter had a small footprint of 0.85×0.75 mm.

Table 8 shows geometric parameters for the fabricated 2-layer series and shunt resonators of the fabricated 2-layer-resonator-based filter.

TABLE 8

| Symbol | Parameter | Series | Shunt |
|---|---|---|---|
| Λ | Cell length (μm) | 6 | 6 |
| Lₑ | Electrode length (μm) | 1 | 1 |
| L_{g} | Gap length (μm) | 2 | 2 |
| N | Number of electrode pairs | 13 | 38 |
| Wₐ | Aperture width (μm) | 50 | 50 |
| Wᵣ | Recessed width (μm) | 45 | 75 |
| T_{LN} | LiNbO₃ thickness (nm) | 85 | 85 |
| T_{Al} | Aluminum thickness (nm) | 350 | 350 |
| T_{a-Si} | Sacrificial a-Si thickness (nm) | 1 | 1 |

The study measured the resonators and the filter using a Keysight vector network analyzer (VNA) in the air at a 15-dBm power level. FIG. 14B shows the admittance response in amplitude (in subpanel a) and phase (in subpanel b) of the resonators, fit with the mmWave MBVD circuit model [73″] shown in FIG. 8B.

A higher frequency resonance of EM nature occurred due to the self-resonance of the reactive parasitic embedded in the resonator routing. Side length (Lₛ) and routing resistance (Rₛ) were fit based on EM resonances. Another effect was that the perceived resonances were now at 26.07 GHz for the series and 18.87 GHz for the shunt, which deviated from the mechanical resonances represented by the emotional elements Lₘ, Cₘ, and Rₘ.

Table 9 shows scattering parameters (i.e., S-parameters) of the fabricated 2-layer series and shunt resonators in the fabricated 2-layer-resonator-based filter.

TABLE 9

| S-parameter | Series | Shunt |
|---|---|---|
| fₛ (GHz) | 27.10 | 21.78 |
| Q | 52 | 40 |
| k² (%) | 22 | 47 |
| C₀ (fF) | 51 | 164 |
| Lₛ (nH) | 0.22 | 0.17 |
| Rₛ (Ω) | 4.8 | 1.9 |

As shown in Table 9, measurements showed Q around 40 and a high k² of around 47%. The study obtained k² via MBVD fitting (shown in FIG. 8B), which was smaller than the perceived k² calculated from frequency shift (fₛ) and parallel resonance (fₚ) due to the existence of side length (Lₛ) [73″]. Q was defined as the anti-resonance due to the inclusion of side resistance (Rₛ) and side length (Lₛ).

In FIG. 14C, subpanel (a) shows the measured filter response under 50Ω. The 23.8-GHz filter exhibited a low IL of 1.52-dB, a wide 3-dB FBW of 19.4%, a 30-dB Shape Factor of 2.08, and an OoB rejection of 12.1 dB, matching filter simulation. The measured filter response under resistance matched 34.7Ω in FIG. 14C, subpanel b, shows a passband centered at 23.6 GHz with insertion loss (IL) of 1.39 dB, broad 3-dB FBW of 19.1%, OoB rejection of 12.8- and 30-dB Shape Factor of 2.16. As shown in FIG. 14D, compared with SoA low-loss acoustic filters, the fabricated 2-layer-resonator-based filter showed significant frequency scaling and FBW enhancement.

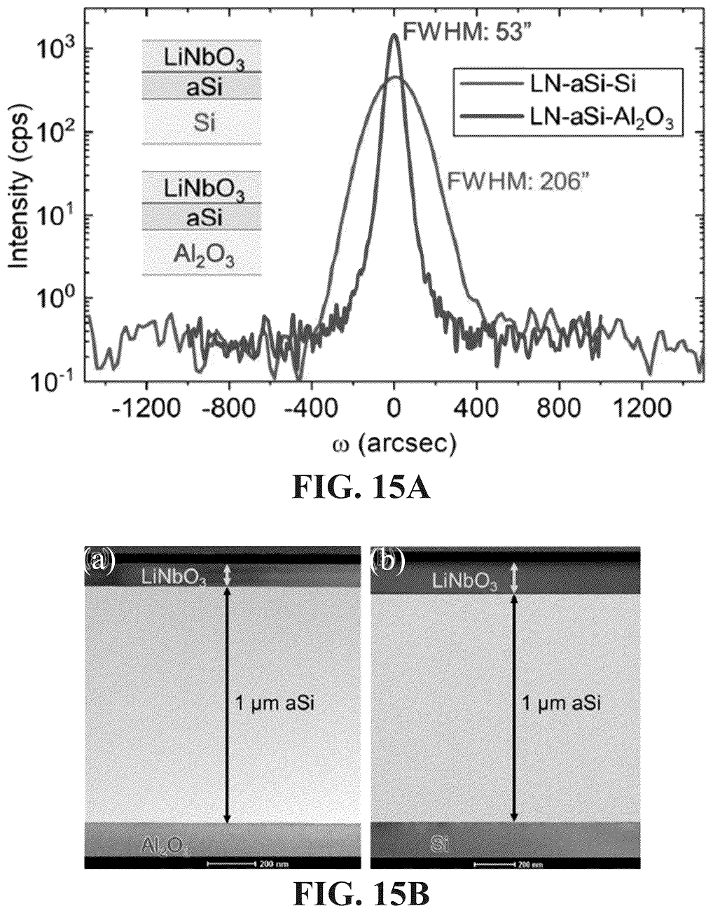

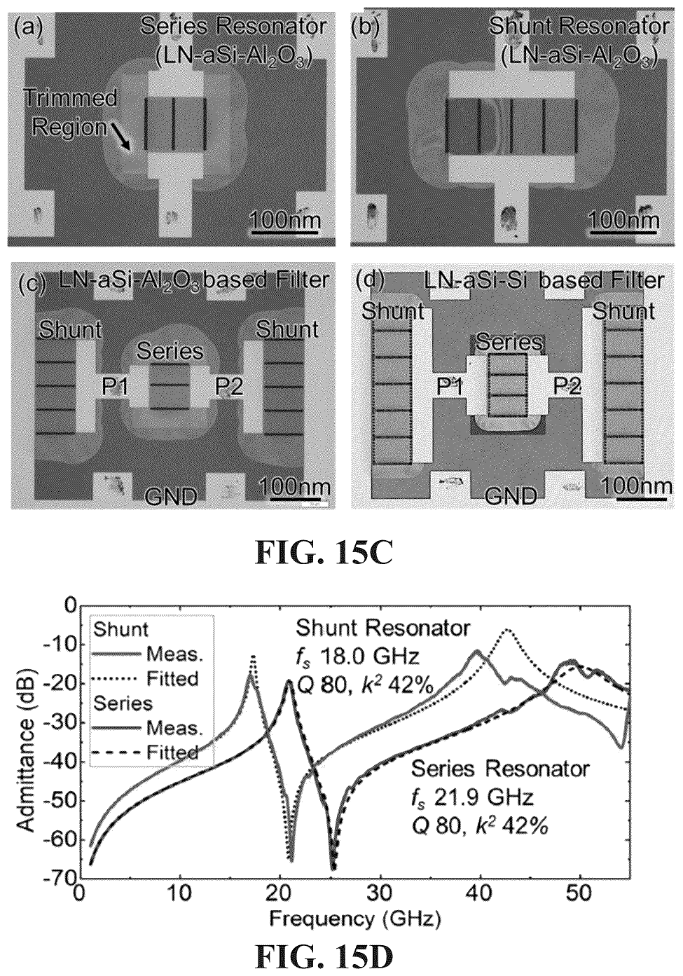

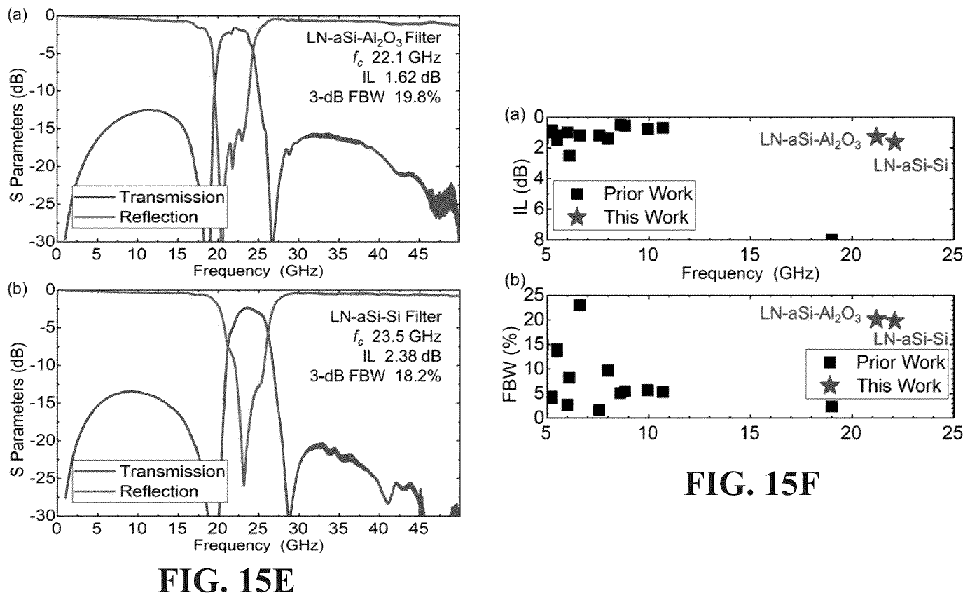

Fabricated Al₂O₃/Si-based filter. The study purchased and analyzed the two stacks (e.g., LN-aSi-Si & LN-aSi-Al₂O₃) using material characterization techniques. First, the study measured rocking curves using high-resolution x-ray diffraction (HRXRD) to validate the crystal quality of the material stacks as shown in FIG. 15A. FIG. 15A shows full width at half maximum (FWHM) of 53″ for LN-aSi-Al₂O₃ and 206″ for LN-aSi-Si, comparable to FWHM in other thin film LiNbO₃ layers. Next, the study measured side profile images of the stack using transmission electron microscopy (TEM). FIG. 15B shows the TEM images of the LN-aSi-Al₂O₃ and LN-aSi-Si stacks. In FIG. 15B, clean interfaces between material boundaries are illustrated, suggesting good crystallinity of the materials. The images in FIG. 15B also revealed a slightly thicker LiNbO₃ layer for the LN-aSi-Si compared to the LN-aSi-Al₂O₃ stack, which suggested small thickness variations across the wafers.

The fabrication process initiates by trimming the LiNbO₃ thickness of the samples down to 90 nm, which provides the base start thickness used for the shunt resonators. The trimming was done using ion milling [103]. Afterward, the study patterned etching windows using lithography and etched into the aSi layer. The long lateral etch windows divided the devices into resonator banks, expediting the release process. Next, the study defined local regions for the placement of the series resonators using lithography. Afterward, the study used a second round of ion milling on these exposed local trimming regions for a target thickness of 75 nm. The study monitored the step height difference between these regions using atomic force microscopy (AFM), with a measured height of 15±1 nm. The study used electron-beam lithography (EBL) to pattern the fine features of the metal layer, and the study evaporated Al for the metal deposition. The study then released the acoustic resonator by selectively etching the aSi intermediate layer using xenon difluoride (XeF₂).

The study then integrated one fabricated Al₂O₃-based series resonator and two Al₂O₃-based shunt resonators into an mmWave filter, generating a fabricated LN-aSi-Al₂O₃-based filter (i.e., fabricated Al₂O₃-based filter). The study also integrated one fabricated Si-based series resonator and two Si-based shunt resonators into an mmWave filter, generating a fabricated LN-aSi—Si-based filter (i.e., fabricated Si-based filter).

FIG. 15C shows the optical images of the fabricated Al₂O₃-based series resonator (i.e., LN-aSi-Al₂O₃-based series resonator, in subpanel a), the fabricated Al₂O₃-based shunt resonator (i.e., LN-aSi-Al₂O₃-based shunt resonator, in subpanel b), the fabricated LN-aSi-Al₂O₃-based filter (i.e., Al₂O₃-based filter, in subpanel c), and the fabricated Ln-aSi—Si-based filter (i.e., Si-based filter, in subpanel d).

The study measured the fabricated Al₂O₃-based resonators at room temperature using a 67 GHz Keysight VNA. FIG. 15D shows the admittance response for the fabricated Al₂O₃-based series and shunt resonators, wherein the fabricated series and shunt resonators exhibited nearly identical figures of merit, with k² of 42% and Q of 80. The study extracted k² using MBVD (shown in FIG. 8B) and considering the series routing resistance and inductance observed in interdigital transducers (IDT) devices. A good overlap between the fₚ of the fabricated shunt resonator and the fₛ of the fabricated shunt resonator may be observed around 22 GHz, corroborating the accuracy of the local trim.

FIG. 15E, subpanel (a) shows the filter response for the fabricated Al₂O₃-based filter. As shown in subpanel (a), the fabricated Al₂O₃-based filter had IL of 1.62 dB, and FBW of 19.8% at 22.1 GHz f_{c}. FIG. 15E, subpanel (b) shows the filter response for the fabricated Si-based filter. As shown in subpanel (b), the fabricated Si-based filter had a 2.38 dB IL with 18.2% FBW at the center frequency (f_{c}) of 23.5 GHz.

The measurements for the fabricated filters and standalone fabricated resonators were in good agreement with the simulations. The discrepancy in f_{c} between the 2 filters was due to the small variations in the thickness of the LiNbO₃ layer across the sample surface. These experimental results showed remarkable frequency scaling and improved FBW compared to the SoA filters shown in FIG. 15F while maintaining low IL. The out-of-band characteristics were similar to other and previous studies using 3 resonator ladder filters [84], [108].

### Discussion

Mobile communication systems rely heavily on acoustic devices for sub-6 GHz front-end filtering and signal processing [1′]. Achieving high-performance acoustic resonators at millimeter wave (mm-wave) would allow for the deployment of compact filters. However, scaling acoustic resonators to higher frequencies has posed a significant challenge, with a large performance degradation occurring above 6 GHz. In order to synthesize filters, higher quality factors (Q) and electromechanical coupling (k²) are desired to increase the figure of merit (FoM, Q·k²) of resonators at mm-wave. By employing the use of a novel film stack and the use of higher order first and third antisymmetric (A1 and A3, respectively) bulk acoustic tones, the study demonstrated record-breaking FoM performance at mm-wave.

Many material platforms have been considered for achieving high-performance acoustics at mm-Wave, including aluminum nitride (AlN) [4″], scandium aluminum nitride (ScAlN) [5″], [6″], lithium niobate (LiNbO₃) [7″], [8″] and lithium tantalate (LiTaO3) [9″]. Of these, suspended thin film LiNbO₃ utilizing thickness-shear modes is a strong contender thanks to a large intrinsic electromechanical coupling and material Q [10″]-[12″]. Additionally, this platform does not depend on ultra-fine lateral feature sizes to achieve frequency scaling. However, to scale this design topology to higher frequencies, thinner films are required, in turn reducing device Q [13″]. To overcome this, periodically poled piezoelectric films (P3F) have been proposed to increase the total structure thickness while maintaining k² [14″], [15″]. While two-layer demonstrations in LiNbO₃ have been shown to offer high performance [16″]-[18″], increasing to more piezoelectric layers is conjectured to further improve Q. The study presented the first implementation of a three-layer P3F LiNbO₃ resonator. The suspended P3F platform enables high Q resonances at mm-Wave, with fQ products that match or exceed state of the art (SoA) at high frequency.

Increasing the operation frequencies of acoustic resonators is simple in principle, but maintaining device performance is challenging [90]. More specifically, achieving simultaneously high quality factor (Q) and electromechanical coupling (k²) at mmWave is difficult [91]-[98]. For surface acoustic wave (SAW), reducing the electrode width translates to shorter wavelengths and higher frequencies, but this method is contingent on feature size (sub-100 nm) and is thus limited by lithography [99], [100]. Besides, the routing resistance and self-inductance of interdigitated electrodes exacerbate for narrower electrodes. For bulk acoustic wave (BAW), the frequency is inversely proportional to the piezoelectric layer's thickness, while at mmWave, the film stack becomes significantly thin (sub-100 nm), causing challenges in maintaining piezoelectric film quality and lowering electrical loss [101]. Additionally, the resonators required to realize a 50Ω matched filter should be very small to obtain the low values of static capacitance (C₀) required for the network, which inevitably results in lossy devices [6], [26]. Thus, a new piezoelectric acoustic platform (e.g. Al₂O₃-based or Si-based) at mmWave may be needed.

Compact radio frequency (RF) front-end filter components are indispensable in mobile devices. Among various filter technologies [22], acoustic resonator-based filters are unique, providing four orders of magnitude smaller sizes and better frequency selectivity [23]-[25]. Acoustic resonators convert electrical signals to mechanical vibrations and vice versa through piezoelectricity [26]. Thus, one can process electrical signals in acoustics while benefiting from shorter wavelengths and better energy confinement [25]. In incumbent RF front ends, thin-film bulk acoustic wave resonators (FBAR) and surface acoustic wave (SAW) devices are the undisputable champions [27], [28]. In the sub-6 GHz band, there exists plenty of commercial and academic work with excellent demonstrated performance, using aluminum nitride/scandium aluminum nitride (AlN/ScAlN) [29]-[31] and lithium niobate/lithium tantalate (LiNbO₃/LiTaO₃) [32]-[36]. With the ever-growing demand for wireless bandwidth, RF front-end devices keep developing into millimeter-wave (mmWave), toward higher frequency and wider fractional bandwidth (FBW). It would be great if acoustic technologies could be scaled into mmWave while maintaining low loss and compact sizes [37].

Nevertheless, achieving mmWave acoustic filters is not trivial due to the limited availability of acoustic resonators at mmWave. One frequency scaling method uses smaller feature sizes or thinner films [38]-[42], which inevitably suffers from excessive loss, i.e., lower quality factor (Q) and higher insertion loss (IL), from film damage during deposition/transfer and device fabrication. The other frequency scaling uses a higher-order mode in thicker films [43], [44], which is intrinsically limited by reduced electromechanical coupling (k²), resulting in higher IL and lower FBW.

More recently, first-order antisymmetric (A1) mode resonators have been demonstrated at mmWave, using thin-film LiNbO₃ transferred on low-loss substrates with an intermediate amorphous silicon (a-Si) layer [45], [46]. This resonator platform, combined with the EM-acoustic co-design, may be the key to unlocking mmWave acoustic filters. The study presented a third-order filter at 23.5 GHz in thin-film LiNbO₃. The design exhibits an IL of 2.38 dB and an FBW of 18.2%, surpassing the state-of-the-art (SoA). The filter has a small footprint of 0.56 mm². These unprecedented results pave the way for next-generation mmWave acoustic filters.

It is unclear whether it is feasible to frequency scale application-worthy acoustic filters into mmWave. In conventional platforms, the insertion loss (IL) and fractional bandwidth (FBW) dramatically degrade beyond 6 GHz [53″], [54″], [56″]-[58″], [59″]-[64″]. Scaling conventional acoustic devices has been limited by fabrication challenges from either very thin films or very small lateral feature sizes [65″], [66″]. Thin piezoelectric films tend to suffer from worse crystalline quality, while narrow electrodes introduce too much resistive loss. New platforms are required.

Recently, first-order antisymmetric mode (A1) resonators in sub-100 nm LiNbO₃ on sapphire substrate with intermediate amorphous silicon (a-Si) are demonstrated as low-loss and wideband mmWave platforms [67″], [68″]. Innovative design and advanced thin-film transfer collectively enable filters at 20 GHz in the state-of-the-art (SoA). Despite the great performance, the thin-film filters inherit a few issues. First, the thermal nonlinearity is severe [69″], as the thin membrane has a large thermal resistance. Second, the footprints are large, as the lateral field excited structure has low capacitance density in thin films. The long traces, no longer electrically short, introduce undesired EM effects impacting filter performance [70″]. Third, the loss in resonators is still high, marked by a moderate quality factor (Q), intrinsically from the surface damping caused by the large surface-to-volume ratio [71″], [72″].

The study demonstrated the first mmWave acoustic filters using 150 nm 2-layer periodically poled piezoelectric film (P3F) LiNbO₃, achieving low IL of 1.52- and 3-dB FBW of 19.4%, surpassing SoA. The P3F structure promises better Q, smaller footprints, and better linearity. Upon further development, the reported P3F LiNbO₃ platform is promising for compact filters at mmWave.

### CONCLUSION

It must also be noted that, as used in the specification and the appended claims, the singular forms “a,” “an,” and “the” include plural referents unless the context clearly dictates otherwise. Ranges may be expressed herein as from “about” or “5 approximately” one particular value and/or to “about” or “approximately” another particular value. When such a range is expressed, other exemplary embodiments include one particular value and/or the other particular value.

By “comprising” or “containing” or “including,” is meant that at least the name compound, element, particle, or method step is present in the composition or article or method but does not exclude the presence of other compounds, materials, particles, method steps, even if the other such compounds, material, particles, method steps have the same function as what is named.

In describing example embodiments, terminology will be resorted to for the sake of clarity. It is intended that each term contemplates its broadest meaning as understood by those skilled in the art and includes all technical equivalents that operate in a similar manner to accomplish a similar purpose. It is also to be understood that the mention of one or more steps of a method does not preclude the presence of additional method steps or intervening method steps between those steps expressly identified. Steps of a method may be performed in a different order than those described herein without departing from the scope of the present disclosure. Similarly, it is also to be understood that the mention of one or more components in a device or system does not preclude the presence of additional components or intervening components between those components expressly identified.

The following patents, applications and publications as listed below and throughout this document are hereby incorporated by reference in their entirety herein.

### REFERENCE LIST #1

[1] R. Ruby, IEEE Microwave Magazine, vol. 16, no. 7, pp. 46-59, 2015.
[2] S. Gong et al., IEEE Journal of Microwaves, vol. 1, no. 2, pp. 601-609, 2021.
[3] R. Lu et al., Journal of Microelectromechanical Systems, vol. 30, no. 4, pp. 632-641, 2021.
[4] R. Lu et al., Journal of Microelectromechanical Systems, vol. 30, no. 6, pp. 876-884, 2021.
[5] T. Kimura et al., IEEE Transactions on Microwave Theory and Techniques, vol. 67, no. 3, pp. 915-921, 2019.
[6] R. Lu et al., Journal of Micromechanics and Microengineering, vol. 31, no. 11, p. 114001, 2021.
[7] L. Colombo et al., IEEE Int. Ultrason. Symp., pp. 1-4, 2017.
[8] G. Esteves et al., Applied Physics Letters, vol. 118, no. 17, p. 171902, 2021.
[9] M. Rinaldi et al., IEEE Int. Conf. Micro Electro Mech. Syst, pp. 916-919, 2009.
[10] Z. Schaffer et al., IEEE Microwave and Wireless Components Letters, 2022.
[11] Y. Yang et al., IEEE Transactions on Microwave Theory and Techniques, vol. 68, no. 12, pp. 5211-5220 October 2020.
[12] D. Mo et al., arXiv preprint arXiv: 2205.03446, 2022.
[13] M. Hara et al., IEEE Int. Ultrason. Symp., pp. 851-854, 2009.
[14] Y. Shen et al., IEEE Int. Electron Devices Meeting, 2019.
[15] R. Lu et al., IEEE Int. Freq. Control Symp., 2021.
[16] R. Lu et al., Journal of Microelectromechanical Systems, vol. 29, no. 5, pp. 1332-1346 October 2020.
[17] S. Link et al., IEEE Int. Ultrason. Symp., pp. 1-4, 2021.
[18] R. Lu et al., Journal of Microelectromechanical Systems, vol. 29, no. 3, pp. 313-319, June 2020.
[19] R. Lu et al., IEEE Transactions on Microwave Theory and Techniques, vol. 69, no. 7, pp. 3246-3254, 2021.
[20] M. E. Liao et al., CS ManTech Conference, p. 339, 2022.
[21] D. A. Feld et al., IEEE Int. Ultrason. Symp., pp. 431-436, 2008.
[22] R. V Snyder, G. Macchiarella, S. Bastioli, and C. Tomassoni, “Emerging Trends in Techniques and Technology as Applied to Filter Design,” IEEE Journal of Microwaves, vol. 1, no. 1, pp. 317-344, 2021.
[23] R. Lu and S. Gong, “RF acoustic microsystems based on suspended lithium niobate thin films: advances and outlook,” Journal of Micromechanics and Microengineering, vol. 31, no. 11, p. 114001, 2021.
[24] S. Gong, R. Lu, Y. Yang, L. Gao, and A. E. Hassanien, “Microwave Acoustic Devices: Recent Advances and Outlook,” IEEE Journal of Microwaves, vol. 1, no. 2, pp. 601-609, 2021.
[25] R. Ruby, “A Snapshot in Time: The Future in Filters for Cell Phones,” IEEE Microw Mag, vol. 16, no. 7, pp. 46-59, 2015.
[26] A. Hagelauer et al., “From Microwave Acoustic Filters to Millimeter-Wave Operation and New Applications,” IEEE Journal of Microwaves, vol. 3, no. 1, pp. 484-508, 2023.
[27] R. Aigner, G. Fattinger, M. Schaefer, K. Karnati, R. Rothemund, and F. Dumont, “BAW filters for 5G bands,” in 2018 IEEE International Electron Devices Meeting (IEDM), IEEE, 2018, pp. 14-15.
[28] R. Aigner, “SAW and BAW technologies for RF filter applications: A review of the relative strengths and weaknesses,” in IEEE Ultrasonics Symposium, 2008, pp. 582-589.
[29] R. Vetury, A. S. Kochhar, and J. B. Shealy, “XBAW, An Enabling Technology for Next Generation Resonators and Filter Solutions for 5G and Wi-Fi 6/6E/7 applications,” in IEEE IEDM, 2022, pp. 16.1.1-16.1.4.
[30] R. Vetury, M. D. Hodge, and J. B. Shealy, “High Power, Wideband Single Crystal XBAW Technology for sub-6 GHz Micro RF Filter Applications,” in IEEE IUS, 2018, pp. 206-212.
[31] D. Kim et al., “Wideband 6 GHz RF Filters for Wi-Fi 6E Using a Unique BAW Process and Highly Sc-doped AlN Thin Film,” in 2021 IEEE MTT-S International Microwave Symposium (IMS), 2021, pp. 207-209.
[32] T. Kimura, M. Omura, Y. Kishimoto, and K. Hashimoto, “Comparative Study of Acoustic Wave Devices Using Thin Piezoelectric Plates in the 3-5-GHz Range,” IEEE Trans Microw Theory Tech, vol. 67, no. 3, pp. 915-921, 2019.
[33] Y. Yang, R. Lu, L. Gao, and S. Gong, “4.5 GHz Lithium Niobate MEMS Filters With 10% Fractional Bandwidth for 5G Front-Ends,” Journal of Microelectromechanical Systems, vol. 28, no. 4, pp. 575-577, 2019.
[34] L. Zhang et al., “High-Performance Acoustic Wave Devices on LiTaO3/SiC Hetero-Substrates,” IEEE Trans Microw Theory Tech, pp. 1-11, 2023.
[35] P. J. Turner et al., “5 GHz Band n79 wideband microacoustic filter using thin lithium niobate membrane,” Electron Lett, vol. 55, no. 17, pp. 942-944, August 2019.
[36] R. Su et al., “Scaling Surface Acoustic Wave Filters on LNOI platform for 5G communication,” in 2022 International Electron Devices Meeting (IEDM), 2022, pp. 4.2.1-4.2.4.
[37] Y. Yang, R. Lu, and S. Gong, “Scaling Acoustic Filters Towards 5G,” in IEEE International Electron Devices Meeting (IEDM), 2018, pp. 39.6.1-39.6.4.
[38] M. Rinaldi, C. Zuniga, and G. Piazza, “5-10 GHz AlN Contour-Mode Nanoelectromechanical Resonators,” in IEEE International Conference on Micro Electro Mechanical Systems, 2009, pp. 916-919.
[39] V. J. Gokhale, M. T. Hardy, D. S. Katzer, and B. P. Downey, “X-Ka Band Epitaxial ScAlN/AlN/NbN/SiC High-Overtone Bulk Acoustic Resonators,” IEEE Electron Device Letters, vol. 44, no. 4, pp. 674-677, 2023.
[40] W. Zhao et al., “15-GHz Epitaxial AlN FBARs on SiC Substrates,” IEEE Electron Device Letters, p. 1, 2023.
[41] S. Nam, W. Peng, P. Wang, D. Wang, Z. Mi, and A. Mortazawi, “An mm-Wave Trilayer AlN/ScAlN/AlN Higher Order Mode FBAR,” IEEE Microwave and Wireless Technology Letters, 2023.
[42] Z. Schaffer, P. Simeoni, and G. Piazza, “33 GHz Overmoded Bulk Acoustic Resonator,” IEEE Microwave and Wireless Components Letters, vol. 32, no. 6, pp. 656-659, 2022.
[43] G. Giribaldi, L. Colombo, P. Simeoni, and M. Rinaldi, “Compact and wideband nanoacoustic pass-band filters for future 5G and 6G cellular radios,” https://doi.org/10.21203/rs.3.rs-2569732/v1, February 2023.
[44] L. Gao, Y. Yang, and S. Gong, “Wideband hybrid monolithic lithium niobate acoustic filter in the K-band,” IEEE Trans Ultrason Ferroelectr Freq Control, vol. 68, no. 4, pp. 1408-1417, 2020.
[45] J. Kramer et al., “57 GHz Acoustic Resonator with k2 of 7.3% and Q of 56 in Thin-Film Lithium Niobate,” in 2022 International Electron Devices Meeting (IEDM), 2022, pp. 16.4.1-16.4.4.
[46] J. Kramer et al., “Thin-Film Lithium Niobate Acoustic Resonator with High Q of 237 and k2 of 5.1% at 50.74 GHz,” in IEEE International Frequency Control Symposium (IFCS), 2023.
[47] E. Guerrero, P. Silveira, J. Verdú, Y. Yang, S. Gong, and P. de Paco, “A Synthesis Approach to Acoustic Wave Ladder Filters and Duplexers Starting With Shunt Resonator,” IEEE Trans Microw Theory Tech, vol. 69, no. 1, pp. 629-638, 2021.
[48] J. Kramer et al., “57 GHz Acoustic Resonator with k2 of 7.3% and Q of 56 in Thin-Film Lithium Niobate,” in IEEE International Electron Devices Meeting (IEDM), 2022, pp. 16.4.1-16.4.4.
[49] R. Lu, Y. Yang, and S. Gong, “Acoustic Loss of GHz Higher-Order Lamb Waves in Thin-Film Lithium Niobate: A Comparative Study,” Journal of Microelectromechanical Systems, vol. 30, no. 6, pp. 876-884, 2021.
[50] V. Chulukhadze et al., “Frequency Scaling Millimeter Wave Acoustic Devices in Thin Film Lithium Niobate,” in IEEE International Frequency Control Symposium (IFCS), 2023.
[51] A. Hagelauer et al., “From Microwave Acoustic Filters to Millimeter-Wave Operation and New Applications,” IEEE Journal of Microwaves, vol. 3, no. 1, pp. 484-508, 2023, doi: 10.1109/JMW.2022.3226415.
[52] R. Aigner, G. Fattinger, M. Schaefer, K. Karnati, R. Rothemund, and F. Dumont, “BAW filters for 5G bands,” in 2018 IEEE International Electron Devices Meeting (IEDM), IEEE, 2018, pp. 14-15.
[53] M. Matthaiou, O. Yurduseven, H. Q. Ngo, D. Morales-Jimenez, S. L. Cotton, and V. F. Fusco, “The road to 6G: Ten physical layer challenges for communications engineers,” IEEE Communications Magazine, vol. 59, no. 1, 2021, doi: 10.1109/MCOM.001.2000208.
[54] K. Hashimoto, RF bulk acoustic wave filters for communications, vol. 66. 2009.
[55] A. Link and P. Warder, “Golden age for filter design: Innovative and proven approaches for acoustic filter, duplexer, and multiplexer design,” IEEE Microw Mag, vol. 16, no. 7, 2015, doi: 10.1109/MMM.2015.2431236.
[56] R. Ruby, “A Snapshot in Time: The Future in Filters for Cell Phones,” IEEE Microw Mag, vol. 16, no. 7, pp. 46-59, 2015, doi: 10.1109/MMM.2015.2429513.
[57] J. Koulakis et al., “XBAR physics and next generation filter design,” in IEEE International Ultrasonics Symposium, IUS, 2021. doi: 10.1109/IUS52206.2021.9593721.
[58] M. Assylbekova, G. Chen, M. Pirro, G. Michetti, and M. Rinaldi, “Aluminum Nitride Combined Overtone Resonator for Millimeter Wave 5g Applications,” in Proceedings of the IEEE International Conference on Micro Electro Mechanical Systems (MEMS), 2021. doi: 10.1109/MEMS51782.2021.9375278.
[59] G. Piazza, P. J. Stephanou, and A. P. Pisano, “Piezoelectric aluminum nitride vibrating contour-mode MEMS resonators,” Journal of Microelectromechanical Systems, vol. 15, no. 6, 2006, doi: 10.1109/JMEMS.2006.886012.
[60] M. Rinaldi, C. Zuniga, and G. Piazza, “5-10 GHz AlN Contour-Mode Nanoelectromechanical Resonators,” in IEEE International Conference on Micro Electro Mechanical Systems, 2009, pp. 916-919. doi: 10.1109/MEMSYS.2009.4805533.
[61] Y. Yang, A. Gao, R. Lu, and S. Gong, “5 GHz lithium niobate MEMS resonators with high FoM of 153,” in Proceedings of the IEEE International Conference on Micro Electro Mechanical Systems (MEMS), 2017. doi: 10.1109/MEMSYS.2017.7863565.
[62] M. Kadota and T. Ogami, “5.4 GHz Lamb wave resonator on LiNbO3 thin crystal plate and its application,” Jpn J Appl Phys, vol. 50, no. 7 PART 2, 2011, doi: 10.1143/JJAP.50.07HD11.
[63] R. Wang, S. A. Bhave, and K. Bhattacharjee, “Design and fabrication of S0 Lamb-wave thin-film lithium niobate micromechanical resonators,” Journal of Microelectromechanical Systems, vol. 24, no. 2, 2015, doi: 10.1109/JMEMS.2014.2384916.
[64] K. Mizutaui and K. Toda, “Analysis of lamb wave propagation characteristics in rotated Y-cut X-propagation LiNbO3 plates,” Electronics and Communications in Japan (Part I: Communications), vol. 69, no. 4, 1986, doi: 10.1002/ecja.4410690406.
[65] K. Umeda, H. Kawamura, M. Takeuchi, and Y. Yoshino, “Characteristics of an AlN-based bulk acoustic wave resonator in the super high frequency range,” Vacuum, vol. 83, no. 3, 2008, doi: 10.1016/j.vacuum.2008.04.044.
[66] W. Zhao et al., “15-GHz Epitaxial AlN FBARs on SiC Substrates,” IEEE Electron Device Letters, p. 1, 2023, doi: 10.1109/LED.2023.3268863.
[67] R. Lu, Y. Yang, S. Link, and S. Gong, “Al Resonators in 128& #x00B0; Y-cut Lithium Niobate with Electromechanical Coupling of 46.4& #x0025;” Journal of Microelectromechanical Systems, 2020, doi: 10.1109/JMEMS.2020.2982775.
[68] V. Plessky et al., “Laterally excited bulk wave resonators (XBARs) based on thin Lithium Niobate platelet for 5 GHz and 13 GHz filters,” in IEEE MTT-S International Microwave Symposium Digest, 2019. doi: 10.1109/mwsym.2019.8700876.
[69] M. Kadota, T. Ogami, K. Yamamoto, H. Tochishita, and Y. Negoro, “High-frequency lamb wave device composed of MEMS structure using LiNbO 3 thin film and air gap,” IEEE Trans Ultrason Ferroelectr Freq Control, vol. 57, no. 11, 2010, doi: 10.1109/TUFFC.2010.1722.
[70] J. Kramer et al., “57 GHz Acoustic Resonator with k2 of 7.3% and Q of 56 in Thin-Film Lithium Niobate,” in IEEE International Electron Devices Meeting (IEDM), 2022, pp. 16.4.1-16.4.4. doi: 10.1109/IEDM45625.2022.10019391.
[71] Z. Schaffer, P. Simeoni, and G. Piazza, “33 GHz Overmoded Bulk Acoustic Resonator,” IEEE Microwave and Wireless Components Letters, vol. 32, no. 6, pp. 656-659, 2022, doi: 10.1109/LMWC.2022.3166682.
[72] V. Chulukhadze et al., “Frequency Scaling Millimeter Wave Acoustic Devices in Thin Film Lithium Niobate,” in IEEE International Frequency Control Symposium (IFCS), 2023.
[73] O. Barrera et al., “Thin-Film Lithium Niobate Acoustic Filter at 23.5 GHz with 2.38 dB IL and 18.2% FBW,” July 2023.
[74] J. Kramer et al., “Thin-Film Lithium Niobate Acoustic Resonator with High Q of 237 and k2 of 5.1% at 50.74 GHz,” in IEEE International Frequency Control Symposium (IFCS), 2023.
[75] Izhar et al., “A K-Band Bulk Acoustic Wave Resonator Using Periodically Poled Al0.72Sc0.28N,” IEEE Electron Device Letters, vol. 44, no. 7, 2023, doi: 10.1109/LED.2023.3282170.
[76] S. Nam, W. Peng, P. Wang, D. Wang, Z. Mi, and A. Mortazawi, “A mm-Wave Trilayer AlN/ScAlN/AlN Higher Order Mode FBAR,” IEEE Microwave and Wireless Technology Letters, vol. 33, no. 6, 2023, doi: 10.1109/lmwt.2023.3271865.
[77] R. Ruby, “A Snapshot in Time: The Future in Filters for Cell Phones,” IEEE Microw Mag, vol. 16, no. 7, pp. 46-59, 2015.
[78] K. Hashimoto, Surface Acoustic Wave Devices in Telecommunications. 2000. doi: 10.1007/978-3-662-04223-6.
[79] J. F. Rosenbaum, Bulk Acoustic Wave Theory and Devices. Artech House, 1988.
[80] A. Hagelauer et al., “From Microwave Acoustic Filters to Millimeter-Wave Operation and New Applications,” IEEE Journal of Microwaves, vol. 3, no. 1, pp. 484-508, 2023.
[81] A. Link and P. Warder, “Golden age for filter design: Innovative and proven approaches for acoustic filter, duplexer, and multiplexer design,” IEEE Microw Mag, vol. 16, no. 7, 2015.
[82] R. Aigner, G. Fattinger, M. Schaefer, K. Karnati, R. Rothemund, and F. Dumont, “BAW filters for 5G bands,” in 2018 IEEE International Electron Devices Meeting (IEDM), IEEE, 2018, pp. 14-15.
[83] D. Kim et al., “Wideband 6 GHz RF Filters for Wi-Fi 6E Using a Unique BAW Process and Highly Sc-doped AlN Thin Film,” in 2021 IEEE MTT-S International Microwave Symposium (IMS), 2021, pp. 207-209.
[84] Y. Yang, R. Lu, L. Gao, and S. Gong, “4.5 GHz Lithium Niobate MEMS Filters With 10% Fractional Bandwidth for 5G Front-Ends,” Journal of Microelectromechanical Systems, vol. 28, no. 4, pp. 575-577, 2019.
[85] L. Gao, Y. Yang, and S. Gong, “Wideband hybrid monolithic lithium niobate acoustic filter in the K-band,” IEEE Trans Ultrason Ferroelectr Freq Control, vol. 68, no. 4, pp. 1408-1417, 2020.
[86] G. Giribaldi, L. Colombo, P. Simeoni, and M. Rinaldi, “Compact and wideband nanoacoustic pass-band filters for future 5G and 6G cellular radios,” https://doi.org/10.21203/rs.3.rs-2569732/v1, Feb. 9, 2023.
[87] L. Zhang et al., “High-Performance Acoustic Wave Devices on LiTaO3/SiC Hetero-Substrates,” IEEE Trans Microw Theory Tech, pp. 1-11, 2023.
[88] Y. Yang, L. Gao, and S. Gong, “An X-band lithium niobate acoustic RFFE Filter with FBW of 3.45% and IL of 2.7 dB,” in IEEE MTT-S International Microwave Symposium Digest, 2020.
[89] R. V Snyder, G. Macchiarella, S. Bastioli, and C. Tomassoni, “Emerging Trends in Techniques and Technology as Applied to Filter Design,” IEEE Journal of Microwaves, vol. 1, no. 1, pp. 317-344, 2021.
[90] S. Gong, R. Lu, Y. Yang, L. Gao, and A. E. Hassanien, “Microwave Acoustic Devices: Recent Advances and Outlook,” IEEE Journal of Microwaves, vol. 1, no. 2, pp. 601-609, 2021.
[91] G. Giribaldi, L. Colombo, and M. Rinaldi, “6-20 GHz 30% ScAlN Lateral Field-Excited Cross-sectional Lame′ Mode Resonators for future mobile RF Front-Ends,” IEEE Trans Ultrason Ferroelectr Freq Control, 2023.
[92] M. Assylbekova et al., “Aluminum Nitride Combined Overtone Resonator for Millimeter Wave 5g Applications,” in Proceedings of the IEEE International Conference on Micro Electro Mechanical Systems (MEMS), 2021.
[93] S. Nam et al., “A mm-Wave Trilayer AlN/ScAlN/AlN Higher Order Mode FBAR,” IEEE Microwave and Wireless Technology Letters, vol. 33, no. 6, 2023.
[94] W. Zhao et al., “15-GHz Epitaxial AlN FBARs on SiC Substrates,” IEEE Electron Device Letters, p. 1, 2023.
[95] Z. Schaffer et al., “A Solidly Mounted 55 GHz Overmoded Bulk Acoustic Resonator,” in 2023 IEEE International Ultrasonics Symposium (IUS), 2003.
[96] Cho S et al., “Millimeter Wave Thin-Film Bulk Acoustic Resonator in Sputtered Scandium Aluminum Nitride,” Journal of Microelectromechanical Systems, 2023.
[97] R. Vetury et al., “A Manufacturable AlScN Periodically Polarized Piezoelectric Film Bulk Acoustic Wave Resonator (AlScN P3F BAW) Operating in Overtone Mode at X and Ku Band,” in IEEE MTT-S International Microwave Symposium Digest, 2023.
[98] S. Cho et al., “55.4 GHz Bulk Acoustic Resonator in Thin-Film Scandium Aluminum Nitride,” in 2023 IEEE International Ultrasonics Symposium (IUS), 2023, pp. 1-4.
[99] G. Piazza, P. J. Stephanou, and A. P. Pisano, “Piezoelectric aluminum nitride vibrating contour-mode MEMS resonators,” Journal of Microelectromechanical Systems, vol. 15, no. 6, 2006.
[100] G. Piazza et al., “Piezoelectric aluminum nitride thin-films for microelectromechanical systems,” MRS Bulletin, vol. 37, no. 11. 2012. doi: 10.1557/mrs.2012.268.
[101] M. Kadota and T. Ogami, “5.4 GHz Lamb wave resonator on LiNbO3 thin crystal plate and its application,” Jpn J Appl Phys, vol. 50, no. 7 PART 2, 2011.
[102] M. Aljoumayly et al. “5G BAW Technology: Challenges and Solutions,” in 2022 IEEE 22nd Annual Wireless and Microwave Technology Conference, WAMICON 2022, 2022.
[103] Y. Yang, A. Gao, R. Lu, and S. Gong, “5 GHz lithium niobate MEMS resonators with high FoM of 153,” in Proceedings of the IEEE International Conference on Micro Electro Mechanical Systems (MEMS), 2017.
[104] R. Lu et al., “A1 resonators in 128° Y-cut Lithium Niobate with Electromechanical Coupling of 46.4%,” Journal of Microelectromechanical Systems, 2020.
[105] J. Kramer et al., “57 GHz Acoustic Resonator with k2 of 7.3% and Q of 56 in Thin-Film Lithium Niobate,” in IEEE International Electron Devices Meeting (IEDM), 2022, pp. 16.4.1-16.4.4.
[106] J. Kramer et al., “Thin-Film Lithium Niobate Acoustic Resonator with High Q of 237 and k2 of 5.1% at 50.74 GHz,” in IEEE International Frequency Control Symposium (IFCS), 2023.
[107] O. Barrera et al., “Thin-Film Lithium Niobate Acoustic Filter at 23.5 GHz with 2.38 dB IL and 18.2% FBW,” Journal of Microelectromechanical Systems, July 2023.
[108] A. Kochhar et al., “X-band Bulk Acoustic Wave Resonator (XBAW) using Periodically Polarized Piezoelectric Films (P3F),” in 2023 IEEE International Ultrasonics Symposium (IUS), 2023, pp. 1-4.

### REFERENCE LIST #2

[1′] R. Ruby, IEEE Microw Mag, 2015.
[2′] J. Kramer et al., Int. Electron Dev. Meeting (IEDM), 2022.
[3′] M. Rinaldi et al., 2009 IEEE 22nd International Conference on Micro Electro Mechanical Systems, 2009.
[4′] Z. Schaffer et al., IEEE Microwave and Wireless Components Letters, 2022.
[5′] Y. Yang et al., IEEE Trans Microw Theory Tech 2020.
[6′] D. Mo et al., IEEE Trans Electron Devices, August 2022.
[7′] M. Hara et al., 2009 IEEE International Ultrasonics Symposium, 2009.
[8′] Y. Shen et al., 2019 IEEE IEDM, 2019.
[9′] R. Lu et al., Journal of Microelectromechanical Systems, 2020.
[10′] R. Lu and S. Gong, IEEE IFCS, 2021.
[11′] S. Link et al., IEEE IUS, 2021.
[12′] R. Lu et al., Journal of Microelectromechanical Systems 2020.

### REFERENCE LIST #3

[1″] R. Ruby, “A snapshot in time: The future in filters for cell phones,” IEEE Microwave Magazine, vol. 16, no. 7, pp. 46-59, 2015.
[2″] S. Gong, R. Lu, Y. Yang, L. Gao, and A. E. Hassanien, “Microwave acoustic devices: Recent advances and outlook,” IEEE Journal of Microwaves, vol. 1, no. 2, pp. 601-609, 2021.
[3″] A. Hagelauer, G. Fattinger, C. C. W. Ruppel, M. Ueda, K.-y. Hashimoto, and A. Tag, “Microwave acoustic wave devices: Recent advances on architectures, modeling, materials, and packaging,” IEEE Transactions on Microwave Theory and Techniques, vol. 66, no. 10, pp. 4548-4562, 2018.
[4″] Z. Schaffer, P. Simeoni, and G. Piazza, “33 ghz overmoded bulk acoustic resonator,” IEEE Microwave and Wireless Components Letters, vol. 32, no. 6, pp. 656-659, 2022.
[5″] A. Ansari, “Single crystalline scandium aluminum nitride: An emerging material for 5g acoustic filters,” in 2019 IEEE MTT-S International Wireless Symposium (IWS), 2019, pp. 1-3.
[6″] S. Cho, J. Kramer, J. Guida, O. A. Barrera, V. Chulukhadze, C. Cui, S. Ghosh, and R. Lu, “Analysis of 5-10 ghz higher-order lamb acous-tic waves in thin-film scandium aluminum nitride,” in 2023 Joint Conference of the European Frequency and Time Forum and IEEE International Frequency Control Symposium (EFTF/IFCS), 2023.
[7″] R. Lu and S. Gong, “Rf acoustic microsystems based on suspended lithium niobate thin films: advances and outlook,” Journal of Micromechanics and Microengineering, vol. 31, no. 11, p. 114001, September 2021. [Online]. Available: https://dx.doi.org/10.1088/1361-6439/ac288f
[8″] T.-H. Hsu, K.-J. Tseng, and M.-H. Li, “Thin-film lithium niobate-on-insulator (lnoi) shear horizontal surface acoustic wave resonators,” Journal of Micromechanics and Microengineering, vol. 31, no. 5, p. 054003, April 2021. [Online]. Available: https://dx.doi.org/10.1088/1361-6439/abf1b5
[9″] M. Kadota, Y. Ishii, and S. Tanaka, “Surface acoustic wave resonators with hetero acoustic layer (hal) structure using lithium tantalate and quartz,” IEEE Transactions on Ultrasonics, Ferroelectrics, and Fre-quency Control, vol. 68, no. 5, pp. 1955-1964, 2021.
[10″] J. Kramer, S. Cho, M. E. Liao, K. Huynh, O. Barrera, L. Matto, M. S. Goorsky, and R. Lu, “57 ghz acoustic resonator with k2 of 7.3% and q of 56 in thin-film lithium niobate,” in 2022 International Electron Devices Meeting (IEDM), 2022, pp. 16.4.1-16.4.4.
[11″] R. Lu and S. Gong, “A 15.8 ghz a6 mode resonator with q of 720 in complementarily oriented piezoelectric lithium niobate thin films,” in 2021 Joint Conference of the European Frequency and Time Forum and IEEE International Frequency Control Symposium (EFTF/IFCS), 2021, pp. 1-4.
[12″] O. Barrera, S. Cho, L. Matto, J. Kramer, K. Huynh, V. Chulukhadze, Y.-W. Chang, M. S. Goorsky, and R. Lu, “Thin-film lithium niobate acoustic filter at 23.5 ghz with 2.38 db il and 18.2% fbw,” 2023.
[13″] V. Chulukhadze, K. Huynh, J. Kramer, M. Liao, S. Cho, L. Matto, O. A. Barrera, C. Cui, M. S. Goorsky, and R. Lu, “Frequency scaling millimeter wave acoustic resonators using ion beam trimmed lithium niobate,” in 2023 Joint Conference of the European Frequency and Time Forum and IEEE International Frequency Control Symposium (EFTF/IFCS), 2023.
[14″] S. Nam, W. Peng, P. Wang, D. Wang, Z. Mi, and A. Mortazawi, “A mm-wave trilayer aln/scaln/aln higher order mode fbar,” IEEE Microwave and Wireless Technology Letters, vol. 33, no. 6, pp. 803-806, 2023.
[15″] R. Vetury, A. Kochhar, J. Leathersich, C. Moe, M. Winters, J. Shealy, and R. H. Olsson, “A manufacturable alscn periodically polarized piezoelectric film bulk acoustic wave resonator (alscn p3f baw) operating in overtone mode at x and ku band,” in 2023 IEEE/MTT-S International Microwave Symposium—IMS 2023, 2023, pp. 891-894.
[16″] J. Kramer, V. Chulukhadze, K. Huynh, O. Barrera, M. Liao, S. Cho, L. Matto, M. S. Goorsky, and R. Lu, “Thin-film lithium niobate acoustic resonator with high q of 237 and k2 of 5.1% at 50.74 ghz,” 2023.
[17″] R. Lu, Y. Yang, S. Link, and S. Gong, “Enabling higher order lamb wave acoustic devices with complementarily oriented piezoelectric thin films,” Journal of Microelectromechanical Systems, vol. 29, no. 5, pp. 1332-1346, 2020.
[18″] J. Kramer, S. Cho, K. Huynh, V. Chulukhadze, O. Barrera, M. S. Goorsky, and R. Lu, “Extracting acoustic loss of high-order lamb modes at millimeter-wave using acoustic delay lines,” in 2023 IEEE/MTT-S International Microwave Symposium—IMS 2023, 2023, pp. 903-906.
[19″] Y. Yang, R. Lu, T. Manzaneque, and S. Gong, “Toward ka band acoustics: Lithium niobate asymmetrical mode piezoelectric mems resonators,” in 2018 IEEE International Frequency Control Symposium (IFCS), 2018, pp. 1-5.
[20″] S. Link, R. Lu, Y. Yang, A. E. Hassanien, and S. Gong, “An al mode resonator at 12 ghz using 160 nm lithium niobate suspended thin film,” in 2021 IEEE International Ultrasonics Symposium (IUS), 2021, pp. 1-4.
[21″] Y. Yang, R. Lu, L. Gao, and S. Gong, “10-60-ghz electromechanical resonators using thin-film lithium niobate,” IEEE Transactions on Microwave Theory and Techniques, vol. 68, no. 12, pp. 5211-5220, 2020.
[22″] G. Giribaldi, L. Colombo, P. Simeoni, and M. Rinaldi, “Compact and wideband nanoacoustic pass-band filters for future 5g and 6g cellular radios,” PREPRINT https://doi.org/10.21203/rs.3.rs-2569732/v1, 2023.
[23″] M. Kadota, T. Ogami, K. Yamamoto, H. Tochishita, and Y. Negoro, “High-frequency lamb wave device composed of mems structure using linbo3 thin film and air gap,” IEEE Transactions on Ultrasonics, Ferroelectrics, and Frequency Control, vol. 57, no. 11, pp. 2564-2571, 2010.
[24″] M. Rinaldi, C. Zuniga, and G. Piazza, “5-10 ghz aln contour-mode nanoelectromechanical resonators,” in 2009 IEEE 22nd International Conference on Micro Electro Mechanical Systems, 2009, pp. 916-919.
[25″] D. Mo, S. Dabas, S. Rassay, and R. Tabrizian, “Complementary-switchable dual-mode shf scandium aluminum nitride baw resonator,” IEEE Transactions on Electron Devices, vol. 69, no. 8, pp. 4624-4631, 2022.
[26″] Y. Shen, P. Patel, R. Vetury, and J. Shealy, “452 mhz bandwidth, high rejection 5.6 ghz unii xbaw coexistence filters using doped aln-on-silicon,” in 2019 IEEE International Electron Devices Meeting (IEDM), 2019, pp. 17.6.1-17.6.4.
[27″] W. Zhao, M. J. Asadi, L. Li, R. Chaudhuri, K. Nomoto, H. G. Xing, J. C. M. Hwang, and D. Jena, “15-ghz epitaxial aln fbars on sic substrates,” IEEE Electron Device Letters, vol. 44, no. 6, pp. 903-906, 2023.
[28″] Izhar, M. M. A. Fiagbenu, P. Musavigharavi, X. Du, J. Leathersich, C. Moe, A. Kochhar, E. A. Stach, R. Vetury, and R. H. Olsson, “A k-band bulk acoustic wave resonator using periodically poled al0.72sc0.28n,” IEEE Electron Device Letters, vol. 44, no. 7, pp. 1196-1199, 2023.
[29″] R. Vetury, M. D. Hodge, and J. B. Shealy, “High power, wideband single crystal xbaw technology for sub-6 ghz micro rf filter applications,” in 2018 IEEE International Ultrasonics Symposium (IUS), 2018, pp. 206-212.
[30″] R. Aigner, G. Fattinger, M. Schaefer, K. Karnati, R. Rothemund, and F. Dumont, “Baw filters for 5g bands,” in 2018 IEEE International Electron Devices Meeting (IEDM), 2018, pp. 14.5.1-14.5.4.
[31″] J. B. Shealy, R. Vetury, S. R. Gibb, M. D. Hodge, P. Patel, M. A. McLain, A. Y. Feldman, M. D. Boomgarden, M. P. Lewis, B. Hosse, and R. Holden, “Low loss, 3.7 ghz wideband baw filters, using high power single crystal aln-on-sic resonators,” in 2017 IEEE MTT-S International Microwave Symposium (IMS), 2017, pp. 1476-1479.
[32″] D. Kim, G. Moreno, F. Bi, M. Winters, R. Houlden, D. Aichele, and J. Shealy, “Wideband 6 ghz rf filters for wi-fi 6e using a unique baw process and highly sc-doped aln thin film,” in 2021 IEEE MTT-S International Microwave Symposium (IMS), 2021, pp. 207-209.
[33″] R. Aigner et al., “BAW filters for 5G bands,” in IEDM Tech. Dig., December 2018, pp. 14.5.1-14.5.4.
[34″] M. Matthaiou et al., “The road to 6G: Ten physical layer challenges for communications engineers,” IEEE Commun. Mag., vol. 59, no. 1, pp. 64-69, January 2021.
[35″] A. Hagelauer et al., “From microwave acoustic filters to millimeter-wave operation and new applications,” IEEE J. Microw., vol. 3, no. 1, pp. 484-508, January 2023.
[36″] G. Piazza, “Piezoelectric resonant MEMS,” in Resonant MEMS: Prin-ciples, Modeling, Implementation, and Applications (Advanced Micro and Nanosystems). Hoboken, NJ, USA: Wiley, 2015.
[37″] R. Lu and S. Gong, “RF acoustic microsystems based on suspended lithium niobate thin films: Advances and outlook,” J. Micromech. Microeng., vol. 31, no. 11, November 2021, Art. no. 114001.
[38″] S. Gong, R. Lu, Y. Yang, L. Gao, and A. E. Hassanien, “Microwave acoustic devices: Recent advances and outlook,” IEEE J. Microw., vol. 1, no. 2, pp. 601-609, April 2021. [39″] R. Ruby, “A snapshot in time: The future in filters for cell phones,” IEEE Microw. Mag., vol. 16, no. 7, pp. 46-59, August 2015.
[40″] Z. Schaffer, A. Hassanien, M. A. Masud, and G. Piazza, “A solidly mounted 55 GHz overmoded bulk acoustic resonator,” in Proc. IEEE Int. Ultrason. Symp. (IUS), September 2023, pp. 1-4.
[41″] G. Giribaldi, P. Simeoni, L. Colombo, and M. Rinaldi, “High-crystallinity 30% scaln enabling high figure of merit X-band microa-coustic resonators for mid-band 6G,” in Proc. IEEE 36th Int. Conf. Micro Electro Mech. Syst. (MEMS), January 2023, pp. 169-172.
[42″] S. Cho et al., “Millimeter wave thin-film bulk acoustic resonator in sputtered scandium aluminum nitride,” J. Microelectromech. Syst., vol. 32, no. 6, pp. 529-532, December 2023.
[43″] R. Vetury et al., “A manufacturable AlScN periodically polarized piezo-electric film bulk acoustic wave resonator (AlScN P3F BAW) operating in overtone mode at X and Ku band,” in IEEE MTT-S Int. Microw. Symp. Dig., June 2023, pp. 891-894.
[44″] S. Cho, Y. Wang, J. Kramer, K. Nguyen, and R. Lu, “Acoustic delay lines in thin-film lithium niobate on silicon carbide,” in IEEE MTT-S Int. Microw. Symp. Dig., June 2022, pp. 809-812.
[45″] S. Cho et al., “Analysis of 5-10 GHz higher-order Lamb acoustic waves in thin-film scandium aluminum nitride,” in Proc. Joint Conf. Eur. Freq. Time Forum IEEE Int. Freq. Control Symp. (EFTF/IFCS), Toyama, Japan, May 2023, pp. 1-4.
[46″] G. Giribaldi, J. Guida, S. Ghosh, and M. Rinaldi, “Low propagation loss X-band impedance matched Lamb mode delay lines in 30% scandium aluminum nitride,” in Proc. IEEE Int. Ultrason. Symp. (IUS), September 2023, pp. 1-4.
[47″] J. Kramer et al., “Extracting acoustic loss of high-order Lamb modes at millimeter-wave using acoustic delay lines,” in IEEE MTT-S Int. Microw. Symp. Dig., June 2023, pp. 903-906.
[48″] G. Esteves et al., “Al0.68Sc0.32N Lamb wave resonators with electrome-chanical coupling coefficients near 10.28%,” Appl. Phys. Lett., vol. 118, no. 17, April 2021, Art. no. 171902.
[49″] L. Colombo, A. Kochhar, C. Xu, G. Piazza, S. Mishin, and Y. Osh-myansky, “Investigation of 20% scandium-doped aluminum nitride films for MEMS laterally vibrating resonators,” in Proc. IEEE Int. Ultrason. Symp. (IUS), September 2017, pp. 1-4.
[50″] M. D. Henry et al., “AlN and ScAlN contour mode resonators for RF filters,” ECS Trans, vol. 77, no. 6, p. 23, April 2017.
[51″] R. H. Olsson et al., “A high electromechanical coupling coefficient SH0 Lamb wave lithium niobate micromechanical resonator and a method for fabrication,” Sens. Actuators A, Phys., vol. 209, pp. 183-190, March 2014.
[52″] J. Kramer et al., “Trilayer periodically poled piezoelectric film lithium niobate resonator,” in Proc. IEEE Int. Ultrason. Symp. (IUS), September 2023, pp. 1-4.
[53″] Y. Yang, R. Lu, L. Gao, and S. Gong, “4.5 GHz lithium niobate MEMS filters with 10% fractional bandwidth for 5G front-ends,” J. Microelectromech. Syst., vol. 28, no. 4, pp. 575-577, August 2019.
[54″] P. J. Turner et al., “5 GHz band N79 wideband microacoustic filter using thin lithium niobate membrane,” Electron. Lett., vol. 55, no. 17, pp. 942-944, August 2019.
[55″] S. Cho et al., “Millimeter wave thin-film bulk acoustic resonator in sputtered scandium aluminum nitride using platinum electrodes,” in Proc. IEEE Int. Conf. Micro Electro Mech. Syst. (MEMS), 2024, pp. 1-4.
[56″] L. Zhang et al., “High-performance acoustic wave devices on LiTaO3/SiC hetero-substrates,” IEEE Trans. Microw. Theory Techn., vol. 71, no. 10, pp. 4182-4192 October 2023.
[57″] R. Su et al., “Scaling surface acoustic wave filters on LNOI platform for 5G communication,” in IEDM Tech. Dig., December 2022, pp. 4.2.1-4.2.4.
[58″] D. Kim et al., “Wideband 6 GHz RF filters for Wi-Fi 6E using a unique BAW process and highly sc-doped AlN thin film,” in IEEE MTT-S Int. Microw. Symp. Dig., June 2021, pp. 207-209.
[59″] R. Vetury, M. D. Hodge, and J. B. Shealy, “High power, wideband single crystal XBAW technology for sub-6 GHz micro RF filter applications,” in Proc. IEEE Int. Ultrason. Symp. (IUS), October 2018, pp. 206-212.
[60″] T. Kimura, M. Omura, Y. Kishimoto, and K. Hashimoto, “Comparative study of acoustic wave devices using thin piezoelectric plates in the 3-5-GHz range,” IEEE Trans. Microw. Theory Techn., vol. 67, no. 3, pp. 915-921, March 2019.
[61″] Y. Yang, L. Gao, and S. Gong, “X-band miniature filters using lithium niobate acoustic resonators and bandwidth widening technique,” IEEE Trans. Microw. Theory Techn., vol. 69, no. 3, pp. 1602-1610 March 2021.
[62″] L. Gao, Y. Yang, and S. Gong, “Wideband hybrid monolithic lithium niobate acoustic filter in the K-band,” IEEE Trans. Ultrason., Ferro-electr., Freq. Control, vol. 68, no. 4, pp. 1408-1417 April 2021.
[63″] M. AlJoumayly, R. Rothemund, M. Schaefer, and W. Heeren, “5G BAW technology: Challenges and solutions,” in Proc. IEEE 22nd Annu. Wireless Microw. Technol. Conf. (WAMICON), April 2022, pp. 1-3.
[64″] G. Giribaldi, L. Colombo, P. Simeoni, and M. Rinaldi, “Compact and wideband nanoacoustic pass-band filters for future 5G and 6G cellular radios,” Nature Commun., vol. 15, no. 1, p. 304, January 2024.
[65″] Z. Schaffer, P. Simeoni, and G. Piazza, “33 GHz overmoded bulk acoustic resonator,” IEEE Microw. Wireless Compon. Lett., vol. 32, no. 6, pp. 656-659, June 2022.
[66″] M. Rinaldi, C. Zuniga, C. Zuo, and G. Piazza, “Super-high-frequency two-port AlN contour-mode resonators for RF applications,” IEEE Trans. Ultrason., Ferroelectr., Freq. Control, vol. 57, no. 1, pp. 38-45, January 2010.
[67″] O. Barrera et al., “Transferred thin film lithium niobate as millimeter wave acoustic filter platforms,” in Proc. IEEE Int. Conf. Micro Electro Mech. Syst. (MEMS), 2024, pp. 1-4.
[68″] O. Barrera et al., “Thin-film lithium niobate acoustic filter at 23.5 GHz with 2.38 dB IL and 18.2% FBW,” J. Microelectromech. Syst., vol. 32, no. 6, pp. 622-625, December 2023.
[69″] J. Segovia-Fernandez and G. Piazza, “Thermal nonlinearities in contour mode AlN resonators,” J. Microelectromech. Syst., vol. 22, no. 4, pp. 976-985, August 2013.
[70″] D. M. Pozar, Microwave Engineering. Hoboken, NJ, USA: Wiley, 2017.
[71″] R. Lu, Y. Yang, and S. Gong, “Acoustic loss of GHz higher-order Lamb waves in thin-film lithium niobate: A comparative study,” J. Microelectromech. Syst., vol. 30, no. 6, pp. 876-884, December 2021.
[72″] M. Rinaldi, C. Zuniga, and G. Piazza, “5-10 GHz AlN contour-mode nanoelectromechanical resonators,” in Proc. IEEE 22nd Int. Conf. Micro Electro Mech. Syst., January 2009, pp. 1-4.
[73″] J. Kramer et al., “57 GHz acoustic resonator with K2 of 7.3% and Q of 56 in thin-film lithium niobate,” in IEDM Tech. Dig., December 2022, pp. 16.4.1-16.4.4.
[74″] R. Lu, Y. Yang, S. Link, and S. Gong, “Enabling higher order Lamb wave acoustic devices with complementarily oriented piezoelectric thin films,” J. Microelectromech. Syst., vol. 29, no. 5, pp. 1332-1346 October 2020.
[75″] S. Nam, W. Peng, P. Wang, D. Wang, Z. Mi, and A. Mortazawi, “A mm-wave trilayer AlN/ScAlN/AlN higher order mode FBAR,” IEEE Microw. Wireless Technol. Lett., vol. 33, no. 6, pp. 803-806, June 2023.
[76″] J. Kramer et al., “Thin-film lithium niobate acoustic resonator with high Q of 237 and k2 of 5.1% at 50.74 GHz,” in Proc. Joint Conf. Eur. Freq. Time Forum IEEE Int. Freq. Control Symp. (EFTF/IFCS), May 2023, pp. 1-4.
[77″] Izhar et al., “A K-band bulk acoustic wave resonator using periodically poled Al0.72Sc0.28N,” IEEE Electron Device Lett., vol. 44, no. 7, pp. 1196-1199 July 2023.
[78″] R. Lu, M.-H. Li, Y. Yang, T. Manzaneque, and S. Gong, “Accurate extraction of large electromechanical coupling in piezoelectric MEMS resonators,” J. Microelectromech. Syst., vol. 28, no. 2, pp. 209-218, April 2019.
[79″] E. Guerrero, P. Silveira, J. Verdu, Y. Yang, S. Gong, and P. de Paco, “A synthesis approach to acoustic wave ladder filters and duplexers starting with shunt resonator,” IEEE Trans. Microw. Theory Techn., vol. 69, no. 1, pp. 629-638, January 2021.
[80″] V. Chulukhadze et al., “Frequency scaling millimeter wave acoustic devices in thin film lithium niobate,” in Proc. IEEE Int. Freq. Control Symp. (IFCS), 2023, pp. 1-4.

What is claimed:

1. An acoustic resonator comprising:
a base substrate of a material with low electromagnetic (EM) loss at frequencies greater than 6 GHz (e.g., sapphire, diamond);
a piezoelectric film layer of lithium niobate (LiNbO₃), lithium tantalate (LiTaO₃), or scandium aluminum nitride, wherein the piezoelectric film layer is suspended over the base substrate; and
an interdigitated electrode (IDE) array formed by a pair of independently addressable microelectrode arrays disposed on a top surface of the piezoelectric film layer, the interdigitated electrode (IDE) array being configured to resonantly vibrate at a range of frequencies greater than 6 GHz,
wherein the piezoelectric film layer was formed over an intermediate or sacrificial layer positioned between the base substrate and the piezoelectric film layer and then etched, or partially etched, such that the piezoelectric film layer is suspended over the base substrate.

2. The acoustic resonator of claim 1, wherein the intermediate layer comprises at least one of amorphous silicon (a-Si), zinc oxide, polycrystalline silicon, single crystal silicon, or benzocyclobutene.

3. The acoustic resonator of claim 1, wherein the intermediate or intermediate layer comprises 1 μm thick layer of amorphous silicon, wherein the intermediate layer serves a sacrificial layer.

4. The acoustic resonator of claim 1, wherein the base substrate comprising the material with low EM loss at frequencies greater than 6 GHz is sapphire.

5. The acoustic resonator of claim 1, wherein the base substrate comprising the material with low EM loss at frequencies greater than 6 GHz is at least one of diamond, quartz, and silicon carbide.

6. The acoustic resonator of claim 1, wherein the base substrate is 500 μm thick.

7. The acoustic resonator of claim 1, wherein the piezoelectric film layer comprises rotated Y-cut LiNbO₃.

8. The acoustic resonator of claim 1, wherein the pair of independently addressable microelectrode arrays are formed of aluminum.

9. The acoustic resonator of claim 1, wherein each electrode of the IDE array is between 1 μm and 100 μm, and wherein each electrode of the IDE array is separated by 1 μm and 100 μm.

10. The acoustic resonator of claim 1, wherein the piezoelectric film layer is formed as a single layer of lithium niobate (LiNbO₃), a single layer of lithium tantalate (LiTaO₃), or a single layer of scandium aluminum nitride.

11. The acoustic resonator of claim 1, wherein the piezoelectric film layer comprises two or more distinct layers of lithium niobate (LiNbO₃), two or more distinct layers of lithium tantalate (LiTaO₃), or two or more distinct layers of scandium aluminum nitride.

12. The acoustic resonator of claim 1, wherein the piezoelectric film layer comprises three or more distinct layers of lithium niobate (LiNbO₃), three or more distinct layers of lithium tantalate (LiTaO₃), or three or more distinct layers of scandium aluminum nitride.

13. The acoustic resonator of claim 1, wherein the piezoelectric film layer comprises two or more distinct layers of lithium niobate (LiNbO₃), lithium tantalate (LiTaO₃), or a combination thereof.

14. The acoustic resonator of claim 1, wherein the resonator is employed in a thin-film bulk acoustic wave resonator (FBAR), a surface acoustic wave (SAW) device, or a mmWave acoustic filter, actuators for digital light processor, or actuators for an opto-quantum device.

15. The acoustic resonator of claim 1, wherein a non-release portion of the intermediate or sacrificial layer is employed as a capacitor or inductor.

16. An integrated circuit comprising an RF filter formed of a acoustic resonator comprising:
a base substrate of a material with low electromagnetic (EM) loss at frequencies greater than 6 GHz (e.g., sapphire, diamond);
a piezoelectric film layer of lithium niobate (LiNbO₃), lithium tantalate (LiTaO₃), or scandium aluminum nitride, wherein the piezoelectric film layer is suspended over the base substrate; and
an interdigitated electrode (IDE) array formed by a pair of independently addressable microelectrode arrays disposed on a top surface of the piezoelectric film layer, the interdigitated electrode (IDE) array being configured to resonantly vibrate at a range of frequencies greater than 6 GHz,
wherein the piezoelectric film layer was formed over an intermediate or sacrificial layer positioned between the base substrate and the piezoelectric film layer and then etched, or partially etched, such that the piezoelectric film layer is suspended over the base substrate.

17. The integrated circuit of claim 16, wherein a first acoustic resonator is employed as a series resonator, and a second acoustic resonator is employed as a shunt resonator in the RF filter.

18. The integrated circuit of claim 16, comprising:
a series resonator and two identical shunt resonators each configured with the acoustic resonator.

19. The integrated circuit of claim 16, wherein the base substrate comprising the material with low EM loss at frequencies greater than 6 GHz is at least one of diamond, quartz, and silicon carbide.

20. A method of fabricating an acoustic resonator, the method comprising:
bonding an intermediate layer to a base substrate of a material with low electromagnetic (EM) loss at frequencies greater than 6 GHz;
bonding a piezoelectric film layer of lithium niobate (LiNbO₃), lithium tantalate (LiTaO₃), or scandium aluminum nitride to the intermediate layer;
etching a cavity at least into the piezoelectric film layer to define an interdigitated electrode (IDE) array on a top surface of the piezoelectric film layer, the IDE array formed by a pair of independently addressable microelectrode arrays; and
etching a portion of the sacrificial layer disposed between the piezoelectric film layer and the base substrate to release the piezoelectric film layer from the base substrate such that at least a portion of the piezoelectric film layer is suspended over the base substrate.
